(19) United States
(12) Patent Application Publication
(10) Pub. No.: US 2026/0271521 A1
(43) Pub. Date: Sep. 10, 2026

(54) DISPLAY DEVICE, ELECTRONIC DEVICE AND METHOD FOR MANUFACTURING THE DISPLAY DEVICE

(71) Applicant: Samsung Display Co., Ltd., Yongin-si (KR)

(72) Inventors: Dong Hee SHIN, Yongin-si (KR); Kyung Ho KIM, Yongin-si (KR); Jung Hwan HWANG, Yongin-si (KR)

(21) Appl. No.: 19/343,916

(22) Filed: Sep. 29, 2025

(30) Foreign Application Priority Data
Mar. 6, 2025 (KR) 10-2025-0028948
May 7, 2025 (KR) 10-2025-0058760

(51) Int. Cl. H10K 59/121; H10K 59/12

(52) U.S. Cl. CPC H10K 59/1213; H10K 59/1201

(57) ABSTRACT

A display device includes: a substrate; a driving transistor including a first bottom electrode and a second bottom electrode on the substrate, an active layer including a first channel region and a second channel region on the first and second bottom electrodes, and a gate electrode on the first and second channel regions; an insulating layer covering the driving transistor; and a light emitting element on the insulating layer, wherein the active layer further includes an offset region located between the first channel region and the second channel region.

### CROSS-REFERENCE TO RELATEDAPPLICATION

The present application claims priority to and the benefit of Korean Patent Application No. 10-2025-0028948; filed on Mar. 6, 2025, and from Korean Patent Application No. 10-2025-0058760 filed on May 7, 2025, in the Korean Intellectual Property Office, the entire disclosure of all of which is incorporated herein by reference herein.

### BACKGROUND

### Field

The present disclosure relates to a display device, an electronic device, and a method for manufacturing the display device.

### Description of the Related Art

With the advancement of the information age, the demand for a display device and an electronic device, which are capable of displaying an image, has increased with various forms. Accordingly, various types of display devices and electronic devices, which include pixels for displaying an image, have been developed. The display device may be provided alone or may be included in the electronic device and used as a display screen of the electronic device.

### SUMMARY

Aspects and features of embodiments of the present disclosure are to provide a display device, an electronic device, and a method for manufacturing the display device, in which operating characteristics of a driving transistor may be improved.

Aspects and features of embodiments of the present disclosure are not limited to those mentioned above and additional aspects and features of embodiments of the present disclosure, which are not mentioned herein, will be clearly understood by those skilled in the art from the following description of the present disclosure.

According to one or more embodiments of the present disclosure, a display device includes: a substrate; a driving transistor including a first bottom electrode and a second bottom electrode on the substrate, an active layer including a first channel region and a second channel region on the first and second bottom electrodes, and a gate electrode on the first and second channel regions; an insulating layer covering the driving transistor; and a light emitting element on the insulating layer, wherein the active layer further includes an offset region located between the first channel region and the second channel region.

In one or more embodiments, the active layer further includes a drain region on one side of the first channel region and a source region on one side of the second channel region, wherein the first bottom electrode is electrically connected to the source region, and wherein the second bottom electrode is electrically connected to the gate electrode.

In one or more embodiments, the display device further includes: a source connection electrode electrically connected to the first bottom electrode and the source region; and a drain connection electrode electrically connected to the drain region.

In one or more embodiments, the gate electrode includes a first portion on the first channel region and a second portion on the second channel region, and wherein the first portion and the second portion of the gate electrode are spaced from each other at a portion where the active layer and the gate electrode overlap each other.

In one or more embodiments, the first bottom electrode and the second bottom electrode are spaced from each other on a same layer.

In one or more embodiments, the first bottom electrode and the second bottom electrode are patterns of different conductive layers arranged on the substrate.

In one or more embodiments, a distance between the first bottom electrode and the first channel region is less than a distance between the second bottom electrode and the second channel region.

In one or more embodiments, the first bottom electrode and the second bottom electrode do not overlap each other in a thickness direction of the substrate.

In one or more embodiments, the first bottom electrode and the second bottom electrode overlap each other below the offset region.

In one or more embodiments, the display device further includes a gate insulating layer between the active layer and the gate electrode, wherein the gate insulating layer covers a portion of the active layer including the first channel region, the second channel region, and the offset region, the gate insulating layer being etched to expose another portion of the active layer.

In one or more embodiments, the active layer includes an oxide semiconductor.

In one or more embodiments, an electronic device includes: a display module including a display panel; and a processor configured to transmit an image data signal to the display module, wherein the display panel includes: a substrate; a driving transistor including a first bottom electrode and a second bottom electrode on the substrate, an active layer including a first channel region and a second channel region on the first and second bottom electrodes, and a gate electrode on the first and second channel regions; an insulating layer covering the driving transistor; and a light emitting element on the insulating layer, wherein the active layer further includes an offset region located between the first channel region and the second channel region.

In one or more embodiments, the active layer further includes a drain region on one side of the first channel region and a source region on one side of the second channel region, wherein the first bottom electrode is electrically connected to the source region, and wherein the second bottom electrode is electrically connected to the gate electrode.

In one or more embodiments, the gate electrode includes a first portion on the first channel region and a second portion on the second channel region, and wherein the first portion and the second portion of the gate electrode are spaced from each other at a portion where the active layer and the gate electrode overlap each other.

In one or more embodiments, a method for manufacturing a display device, the method includes: forming a first bottom electrode and a second bottom electrode, and an insulating layer covering the first bottom electrode and the second bottom electrode, on a substrate; sequentially forming an active layer, a gate insulating layer, and a conductive film, on the insulating layer; forming a mask pattern on the conductive film, the mask pattern overlapping a portion including a central portion of the active layer, having a first thickness at a first portion, and having a second thickness greater than the first thickness at a second portion on respective sides of the first portion; forming a gate electrode below the mask pattern by etching the conductive film using the mask pattern; exposing a portion of the gate electrode by removing the first portion of the mask pattern; etching the portion of the gate electrode; and removing the mask pattern.

In one or more embodiments, the forming the mask pattern includes: forming a photosensitive film on the conductive film; arranging a halftone mask on the photosensitive film and then exposing the photosensitive film using the halftone mask; and forming the mask pattern by developing the photosensitive film.

In one or more embodiments, the exposing the photosensitive film using the halftone mask includes: arranging a half-tone portion of the halftone mask on a portion of the photosensitive film, which corresponds to a portion where the first portion of the mask pattern is to be formed; and arranging a non-tone portion of the halftone mask on another portion of the photosensitive film, which corresponds to a portion where the second portion of the mask pattern is to be formed.

In one or more embodiments, the method further includes etching the gate insulating layer in a form corresponding to the gate electrode before removing the first portion of the mask pattern.

In one or more embodiments, the method further includes forming another portion of the active layer, which is not covered by the gate electrode and the mask pattern, as a source region and a drain region before removing the first portion of the mask pattern.

In one or more embodiments, the method further includes forming an interlayer insulating layer covering the active layer, the gate insulating layer, and the gate electrode; and forming a connection electrode electrically connected to the active layer, on the interlayer insulating layer.

The display device and the electronic device according to embodiments of the present disclosure include a driving transistor including a first channel region, a second channel region, and an offset region located between the first channel region and the second channel region. In one or more embodiments, the driving transistor may further include a first bottom electrode overlapping the first channel region, electrically connected to a source region of the driving transistor, and a second bottom electrode overlapping the second channel region, electrically connected to a gate electrode of the driving transistor. A method of manufacturing a display device according to embodiments of the present disclosure provides a method of manufacturing a display device, including a method of manufacturing the driving transistor.

In the display device, the electronic device, and the method for manufacturing the display device according to embodiments of the present disclosure, the operating characteristics of the driving transistor may be improved by securing a suitable subthreshold slope of the driving transistor. Accordingly, image quality of the display device and the electronic device may be improved.

The effects, aspects, and features of embodiments of the present disclosure are not limited to those mentioned above and more various effects, aspects, and features are included in the following description of the present disclosure.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating a display device according to one or more embodiments;

FIG. 2 is a perspective view illustrating a display module according to one or more embodiments;

FIG. 3 is a plan view illustrating a display panel according to one or more embodiments;

FIG. 4 is a cross-sectional view illustrating a display module according to one or more embodiments;

FIG. 5 is a block diagram illustrating a display device according to one or more embodiments;

FIG. 6 is an equivalent circuit diagram illustrating a subpixel according to one or more embodiments;

FIG. 7 is a plan view illustrating a driving transistor of a subpixel according to one or more embodiments;

FIG. 8 is a plan view illustrating a driving transistor of a subpixel according to one or more embodiments;

FIG. 9 is a cross-sectional view illustrating a display panel according to one or more embodiments;

FIG. 10 is a cross-sectional view illustrating a display panel according to one or more embodiments;

FIG. 11 is a cross-sectional view illustrating a display panel according to one or more embodiments;

FIG. 12 is a plan view illustrating a driving transistor of a subpixel according to one or more embodiments;

FIG. 13 is a cross-sectional view illustrating a display panel according to one or more embodiments;

FIGS. 14 – 24 are cross-sectional views illustrating a method for manufacturing a display device according to one or more embodiments;

FIG. 25 is a block diagram of an electronic device according to one or more embodiments; and

FIG. 26 illustrates schematic diagrams of electronic devices according to various embodiments.

### DETAILEDDESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being "on" another element or layer, it can be directly on the other element or layer, or intervening layers may also be present. The same reference numbers indicate the same components throughout the specification.

It will be understood that, although the terms "first," "second," etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

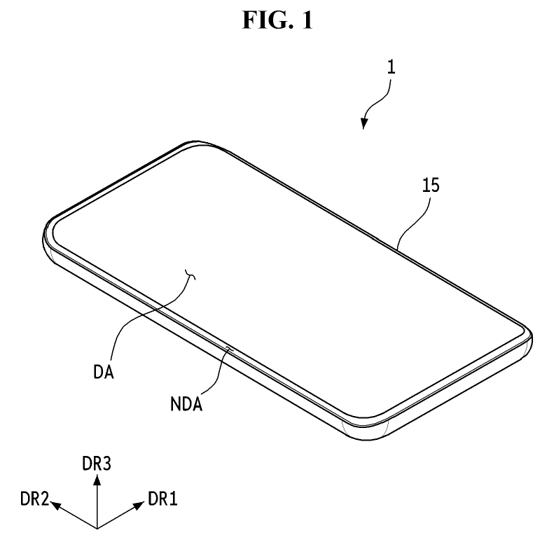

FIG. 1 is a perspective view illustrating a display device according to one or more embodiments.

Referring to FIG. 1, a display device 1 may be a device that may provide an image such as a moving image and/or a still image. For example, the display device 1 includes a display module for implementing a display screen, and thus may be an electronic device capable of displaying an image. Alternatively, the display device 1 may be included in an electronic device that provides a display screen, thereby forming the display screen of the electronic device. For example, the display device 1 may refer to all electronic devices that provide a display screen capable of displaying an image or include a display module for displaying an image.

In one or more embodiments, the display device may be a light emitting display device including a light emitting element such as an inorganic light emitting diode or an organic light emitting diode (OLED), but is not limited thereto. In the present disclosure, an organic light emitting display device including an organic light emitting diode is disclosed as an example of a display device to which embodiments may be applied.

In one or more embodiments, the display device 1 may further include additional elements in addition to the display module. For example, the display device 1 may further include a housing 15 (or a case) accommodating the display module. In FIG. 1, a portion (e.g., a portion including a display area DA and a non-display area NDA) of the display device 1, which is surrounded by the housing 15, may include a display module including a display panel, and may optionally further include a cover window arranged on the display panel.

The display device 1 may have a rectangular shape, a square shape, a circular shape, or other various shapes. The display device 1 may include corner portions having angled or rounded shapes. The display device 1 having a substantially rectangular shape and a rounded corner portion on a plane defined by first and second directions DR1 and DR2 is illustrated in FIG. 1. The display device 1 may have a thickness in a third direction DR3 intersecting the first and second directions DR1 and DR2.

The display device 1 may include a display area DA and a non-display area NDA disposed around the display area DA along an edge or a periphery of the display area DA. The display area DA is an area in which an image may be displayed, and the non-display area NDA is an area in which an image is not displayed. The display area DA may generally occupy the center of the display device 1. The non-display area NDA may be arranged around the display area DA. For example, the non-display area NDA is arranged at an edge of the display device 1, and may surround the display area DA.

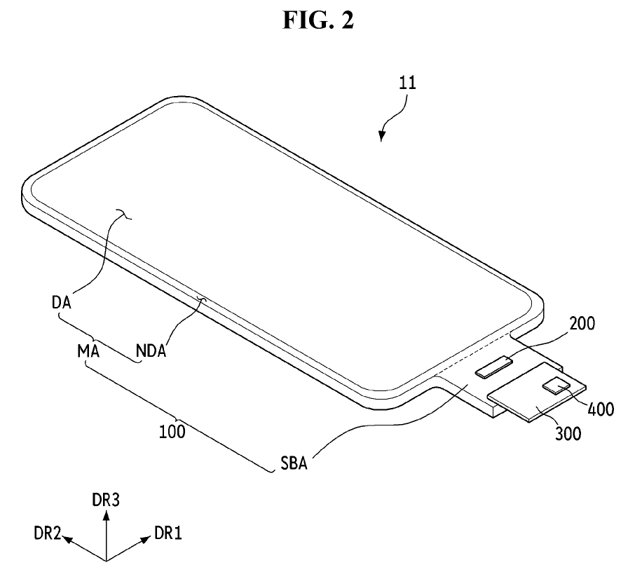

FIG. 2 is a perspective view illustrating a display module according to one or more embodiments. For example, FIG. 2 shows one embodiment of a display module 11 that may be included in the display device 1 of FIG. 1.

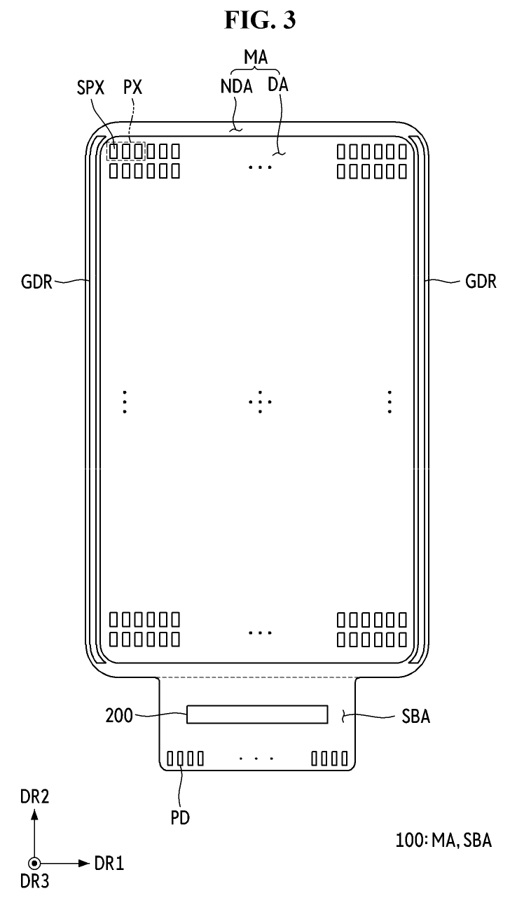

FIG. 3 is a plan view illustrating a display panel according to one or more embodiments. For example, FIG. 3 shows one embodiment of a display panel 100 that may be included in the display module 11 of FIG. 2.

FIGS. 2 and 3 show a display panel 100 including a sub-area SBA, and show a state in which the sub-area SBA of the display panel 100 is unfolded without being bent. The display panel 100 may be bent so that a portion of the sub-area SBA overlaps a main area MA, and thus may be accommodated in the housing 15 of FIG. 1.

Referring to FIGS. 1 – 3, the display device 1 may include a display module 11. The display module 11 may include a display panel 100 for implementing a display screen, a display driver 200 for driving the display panel 100, and a circuit board 300. In one or more embodiments, the display device 1 may provide a touch input function, and the display module 11 may further include a touch driver 400.

The display panel 100 may include a main area MA including a display area DA. The main area MA may further include a non-display area NDA arranged around the display area DA.

Pixels PX for displaying an image may be arranged in the display area DA. Each of the pixels PX may include a plurality of subpixels SPX. The pixel PX may be defined as a group of subpixels of a minimum unit capable of expressing various colors including standard white (e.g., achromatic colors including white of the highest gray level and gray of a middle gray level).

In one or more embodiments, each of the pixels PX may include three subpixels SPX that include a first subpixel for emitting light of a first color, a second subpixel for emitting light of a second color, and a third subpixel for emitting light of a third color. In one or more embodiments, the light of the first color, the light of the second color, and the light of the third color may be red light (e.g., light of a red wavelength band having a main peak wavelength of about 600 nm to about 750 nm), green light (e.g., light of a green wavelength band having a main peak wavelength of about 480 nm to 560 nm), and blue light (e.g., light of a blue wavelength band having a main peak wavelength of about 370 nm to 460 nm), respectively. However, various modifications may be made in the number, type, arrangement structure, and/or emission wavelength of the subpixels SPX included in each of the pixels PX depending on the embodiments.

In one or more embodiments, the subpixels SPX (or the pixels PX including each of the subpixels SPX) may be arranged in a matrix form on the display area DA along the first and second directions DR1 and DR2. However, various modifications may be made in the arrangement structure and arrangement direction of the subpixels SPX and the pixels PX depending on the embodiments.

A pixel area in which each pixel PX is arranged may include light emission areas of the subpixels SPX constituting each pixel PX. When the display panel 100 is a light emitting display panel including light emitting elements, each of the subpixels SPX may include a light emitting element arranged in each light emission area. Each of the subpixels SPX may further include a pixel circuit for controlling the light emitting element. In this case, each pixel area may further include pixel circuit areas in which pixel circuits of the subpixels SPX constituting each pixel PX are arranged. The light emission areas and the pixel circuit areas of each pixel PX may overlap each other, but are not limited thereto.

Lines electrically connected to the subpixels SPX may be arranged in the non-display area NDA. For example, lines connecting the subpixels SPX with the display driver 200 may be arranged in the non-display area NDA. Lines connecting the subpixels SPX with a pad portion and/or the lines connecting the display driver 200 with the pad portion may be further arranged in the non-display area NDA.

In one or more embodiments, at least one driving circuit for driving the subpixels SPX may be further arranged in the non-display area NDA. For example, at least one gate driver GDR may be arranged in the non-display area NDA. Although FIG. 3 shows one embodiment in which two gate drivers GDR are arranged in the non-display area NDA on respective sides of the display area DA, the number and/or position of the gate drivers GDR are/is not limited thereto.

In one or more embodiments, the gate driver GDR may be a panel-embedded driving circuit formed inside the display panel 100 together with the subpixels SPX. For example, the gate driver GDR may include circuit elements formed in a backplane layer of the display panel 100 together with the circuit elements of the subpixels SPX. For example, the gate driver GDR may include a gate signal generator that generates each of gate signals, and the gate signal generator may include a plurality of stages including each of the circuit elements. At least some of the circuit elements of the gate driver GDR and the circuit elements included in the pixel circuits of the subpixels SPX may be formed substantially concurrently (e.g., simultaneously).

In one or more embodiments, the display panel 100 may further include a sub-area SBA extending from the main area MA. In one or more embodiments, the sub-area SBA has a flexible property, and the display panel 100 may be bent in the sub-area SBA so that the sub-area SBA may be arranged below the main area MA. For example, as the display panel 100 is bent in the sub-area SBA, a portion of the sub-area SBA, which includes an area in which the display driver 200 is arranged and an area in which pads PD connected to the circuit board 300 are arranged, may be arranged below the main area MA.

The sub-area SBA may include a display driver 200 and a pad portion. The pad portion may be an area in which the pads PD electrically connected to the circuit board 300 are arranged.

In one or more embodiments, the sub-area SBA may be omitted, and the pad portion may be arranged in the non-display area NDA of the main area MA. In this case, the display driver 200 may be arranged in the non-display area NDA of the main area MA, or may be arranged on the circuit board 300 connected to the display panel 100.

The display driver 200 may output driving signals for driving the display panel 100. The display driver 200 may include a data driver. For example, the display driver 200 may supply data voltages to data lines electrically connected to the subpixels SPX.

In one or more embodiments, the display driver 200 may be arranged on the circuit board 300 in a chip-on-film (COF) mode, and may be electrically connected to the display panel 100 through the pad portion. In one or more embodiments, the display driver 200 may be formed as an integrated circuit (IC), and may be packaged on the display panel 100 in a chip-on-glass (COG) mode, a chip-on-plastic (COP) mode, or an ultrasonic mode.

In one or more embodiments, the display driver 200 may further include a power supply unit configured to generate driving voltages for driving the subpixels SPX, and may supply driving voltages to power lines electrically connected to the subpixels SPX. In one or more embodiments, the power supply unit may be provided separately from the display driver 200, and may be electrically connected to the display panel 100 through the pad portion and/or the like. For example, the power supply unit may be arranged on the circuit board 300, or may be arranged on another circuit board electrically connected to the circuit board 300.

In one or more embodiments, the display driver 200 may further include a timing controller for outputting driving signals necessary for driving the gate driver GDR and the data driver, and driving signals (e.g., a gate control signal and a data control signal) for driving the gate driver GDR and the data driver may be output to the gate driver GDR and the data driver. In one or more embodiments, the timing controller may be provided separately from the display driver 200 and electrically connected to the gate driver GDR and the data driver. For example, the timing controller may be arranged on the circuit board 300, or may be arranged on another circuit board electrically connected to the circuit board 300.

The circuit board 300 is arranged on the pad portion of the display panel 100, and may be electrically connected to the display panel 100 through a conductive material (e.g., an anisotropic conductive film (ACF), etc.). In one or more embodiments, the circuit board 300 may be a flexible printed circuit board (FPCB), a printed circuit board (PCB), or a flexible film such as a chip on film.

The touch driver 400 may be packaged on the circuit board 300. The touch driver 400 may be electrically connected to a touch sensing layer of the display panel 100. In one or more embodiments, the touch sensing layer of the display panel 100 may include touch electrodes constituting a capacitive touch sensor. In this case, the touch driver 400 may detect a touch input by supplying each touch driving signal to the touch electrodes of the touch sensing layer and sensing a change amount of capacitance formed between the touch electrodes. In one or more embodiments, the touch driver 400 may be formed as an integrated circuit (IC).

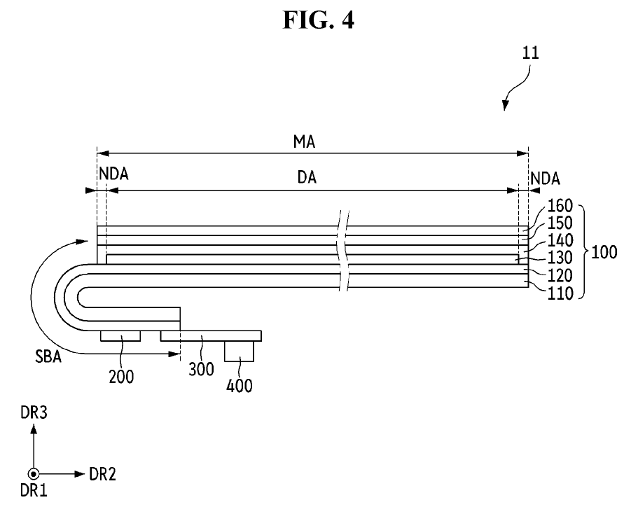

FIG. 4 is a cross-sectional view illustrating a display module according to one or more embodiments. For example, FIG. 4 schematically illustrates an example of a cross-section of the display module 11 in a state that the display panel 100 of FIGS. 2 and 3 is bent in the sub-area SBA.

Referring to FIGS. 2 – 4, the display panel 100 may include a substrate 110, a backplane layer 120, a light emitting element layer 130, and an encapsulation layer 140. In one or more embodiments, the display panel 100 may further include a touch sensing layer 150 and an optical layer 160.

The substrate 110 may be a base member for forming the display panel 100. The substrate 110 may be a flexible substrate capable of being subjected to bending, folding, rolling, and/or the like, but is not limited thereto. In one or more embodiments, the substrate 110 may include a polymer resin such as polyimide (PI). The substrate 110 may also include another material such as glass.

The backplane layer 120 may be arranged on the substrate 110. The backplane layer 120 may include circuit elements (e.g., transistors and a capacitor, which constitute a pixel circuit of each of the subpixels SPX).

The backplane layer 120 may further include lines. For example, the backplane layer 120 may include signal lines and power lines, which are electrically connected to the subpixels SPX.

The signal lines of the backplane layer 120 may include gate lines and data lines, which are electrically connected to the subpixels SPX. The gate lines are electrically connected between the gate driver GDR and the subpixels SPX, and may transmit gate signals (e.g., scan signals and/or emission control signals) to the subpixels SPX. The data lines are electrically connected between the display driver 200 and the subpixels SPX, and may transmit data voltages to the subpixels SPX.

The power lines of the backplane layer 120 may include a plurality of power lines for transmitting a plurality of driving voltages to the subpixels SPX. For example, the power lines of the backplane layer 120 may include a first power line and a second power line, which transmit a first driving voltage and a second driving voltage to the subpixels SPX, respectively. In one or more embodiments, the power lines of the backplane layer 120 may further include at least one of an initialization voltage line for transmitting an initialization voltage to the subpixels SPX or a reference voltage line for transmitting a reference voltage to the subpixels SPX. The type and number of driving voltages supplied to the subpixels SPX may vary depending on the structure or driving mode of the subpixels SPX.

In one or more embodiments, when the display panel 100 includes the gate driver GDR arranged in the non-display area NDA, the backplane layer 120 may further include circuit elements constituting the gate driver GDR, and lines (e.g., signal lines and power lines, which transmit gate control signals for driving the gate driver GDR and driving voltages of the gate driver GDR) electrically connected to the gate driver GDR.

The backplane layer 120 may be arranged in the display area DA, the non-display area NDA, and the sub-area SBA. The circuit elements of the subpixels SPX, and the signal lines and the power lines, which are electrically connected to the subpixels SPX, may be arranged in the display area DA of the backplane layer 120. The signal lines and the power lines of the display area DA may extend to the non-display area NDA of the backplane layer 120, and each of the signal lines and the power lines may be electrically connected to the gate driver GDR, the display driver 200, or the pad PD of the pad portion.

The light emitting element layer 130 may be arranged on the backplane layer 120. The light emitting element layer 130 may include light emitting elements arranged in light emission areas of the subpixels SPX. The light emitting element layer 130 may further include a structure (e.g., a pixel defining layer) defining or partitioning the light emission areas of the subpixels SPX.

The encapsulation layer 140 may be arranged on the light emitting element layer 130. For example, the encapsulation layer 140 may cover an upper surface and sides of the light emitting element layer 130 to protect the light emitting element layer 130.

The touch sensing layer 150 may be arranged on the encapsulation layer 140. However, the position of the touch sensing layer 150 may vary depending on the embodiments. When the display module 11 (or the display device 1) does not provide a touch input function, the display module 11 may not include the touch sensing layer 150. The touch sensing layer 150 may be formed in the display panel 100, but is not limited thereto. The touch sensing layer 150 may be provided separately from the display panel 100, and may be arranged on the display panel 100.

The touch sensing layer 150 may include elements for generating an electrical signal in response to a user’s touch input. For example, the touch sensing layer 150 may include touch electrodes arranged in an area in which a touch input function is provided, and touch lines electrically connecting the touch electrodes with the touch driver 400. When the display module 11 provides a touch input function in the display area DA, the touch electrodes may be arranged in the display area DA. The touch lines may be connected to the touch electrodes in the main area MA (e.g., the display area DA) in which the touch electrodes are arranged. The touch lines may extend to the sub-area SBA and thus may be electrically connected to the plurality of pads PD arranged on the pad portion, and may be electrically connected to the touch driver 400 through the plurality of pads PD.

The optical layer 160 may include an element for adjusting and/or improving optical properties of the display panel 100. For example, the optical layer 160 may include at least one of a color filter layer (e.g., a color filter layer including color filters corresponding to an emission wavelength of each of the subpixels SPX), a polarizing layer, or an anti-reflective layer. The optical layer 160 may be provided integrally with the display panel 100, but is not limited thereto. The optical layer 160 may be omitted.

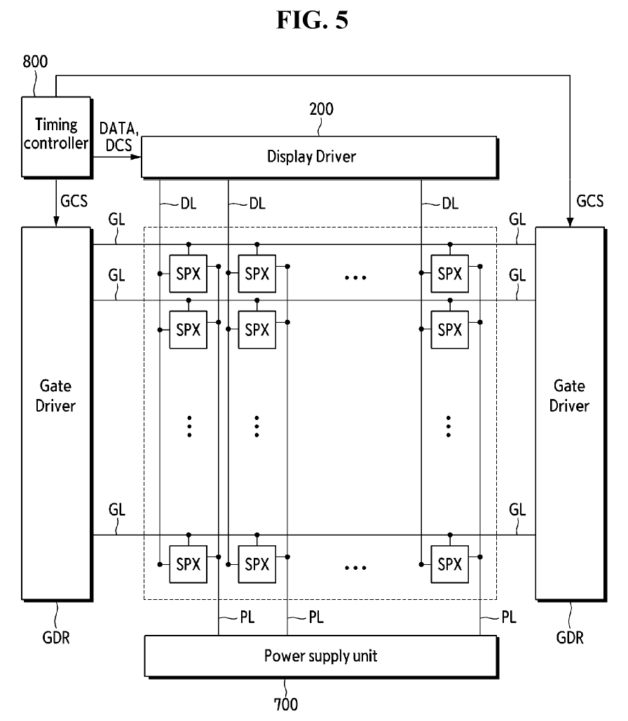

FIG. 5 is a block diagram illustrating a display device according to one or more embodiments. For example, FIG. 5 illustrates an example of elements that may be included in the display device 1 of FIG. 1.

Referring to FIG. 5, the display device 1 according to one or more embodiments may include subpixels SPX, a gate driver GDR, a display driver 200, a power supply unit 700, and a timing controller 800. Although FIG. 5 shows that the display driver 200, the power supply unit 700, and the timing controller 800 are separately provided, the present disclosure is not limited thereto. For example, the power supply unit 700 may be provided separately from the display driver 200, or may be integrated into one integrated circuit together with the display driver 200. In addition, the timing controller 800 may be provided separately from the display driver 200, or may be integrated into one integrated circuit together with the display driver 200.

The subpixels SPX may be electrically connected to the gate lines GL, the data lines DL, and the power lines PL. The subpixels SPX may be electrically connected to the gate driver GDR through the gate lines GL, and may be electrically connected to the display driver 200 through the data lines DL. In addition, the subpixels SPX may be electrically connected to the power supply unit 700 through the power lines PL. The subpixels SPX may be driven by driving signals (e.g., respective gate signals and respective data voltages) and driving voltages, which are supplied from the gate driver GDR, the display driver 200, and the power supply unit 700.

Although FIG. 5 illustrates that the subpixels SPX are connected to the gate driver GDR, the display driver 200, and the power supply unit 700 through one gate line GL, one data line DL, and one power line PL, the present disclosure is not limited thereto. For example, the type and/or number of the signal lines (e.g., the gate lines GL and the data line DL) and the power lines PL, which are connected to each subpixel SPX, may vary depending on the structure or operation mode of the subpixel SPX.

The gate driver GDR and the display driver 200 may output driving signals for driving the subpixels SPX. For example, the gate driver GDR may output the gate signals to the gate lines GL in response to the gate control signal GCS supplied from the timing controller 800. The display driver 200 may output the data voltages to the data lines DL in response to image data DATA and the data control signal DCS, which are supplied from the timing controller 800. For example, the display driver 200 may convert the image data DATA into analog data voltages and output the analog data voltages to the data lines DL.

The power supply unit 700 may output the driving voltages for driving the subpixels SPX. For example, the power supply unit 700 may output a plurality of driving voltages including a first driving voltage of a high potential and a second driving voltage of a low potential.

The timing controller 800 may receive the image data DATA and timing signals from the outside of the display module 11. The timing controller 800 may generate a gate control signal GCS and a data control signal DCS, which are intended for controlling the display panel 100, in accordance with the timing signals. The timing controller 800 may output the gate control signal GCS and the data control signal DCS to the gate driver GDR and the display driver 200, respectively. Also, the timing controller 800 may output the image data DATA to the display driver 200.

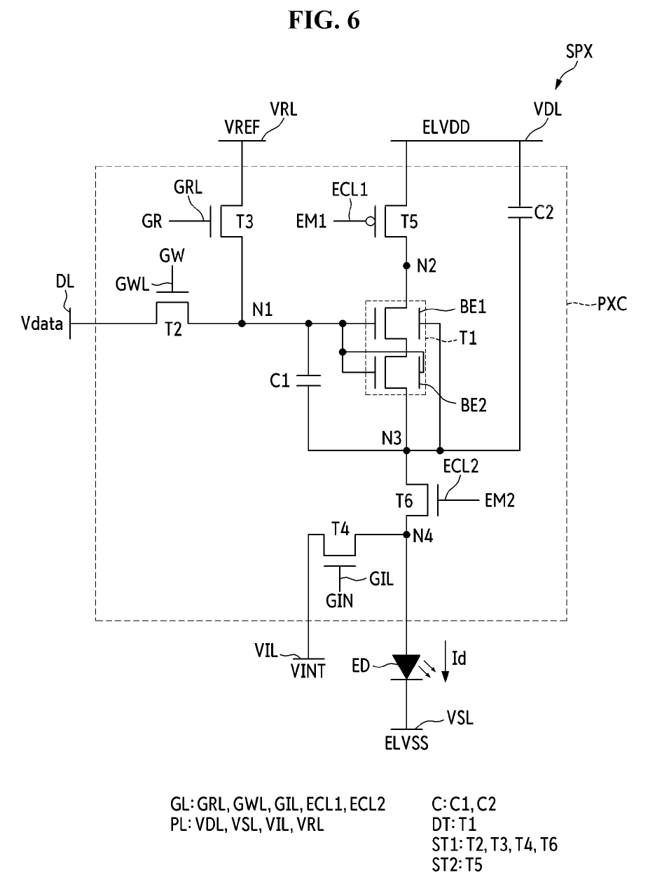

FIG. 6 is an equivalent circuit diagram illustrating a subpixel according to one or more embodiments. For example, FIG. 6 may be an equivalent circuit diagram illustrating a subpixel SPX from among the subpixels SPX of FIGS. 3 and 5. In one or more embodiments, the subpixels SPX constituting each pixel PX may have substantially the same circuit configuration.

Referring to FIG. 6 in addition to FIGS. 1 – 5, the subpixel SPX may include a light emitting element ED and a pixel circuit PXC electrically connected to the light emitting element ED. The light emitting element ED is a light source of the subpixel SPX, and may be, for example, an organic light emitting diode (OLED), but is not limited thereto.

The pixel circuit PXC may supply a driving current Id to the light emitting element ED in response to the driving signals supplied from the gate driver GDR and the display driver 200. For example, the pixel circuit PXC may supply the driving current Id to the light emitting element ED in response to each gate signal supplied from the gate driver GDR through each gate line GL and a data voltage Vdata supplied from the display driver 200 through the data line DL.

In one or more embodiments, the subpixel SPX may be electrically connected to a first gate line GWL transmitting a first gate signal GW (e.g., a scan signal), a second gate line GIL transmitting a second gate signal GIN, a third gate line GRL transmitting a third gate signal GR, a first emission control line ECL1 transmitting a first emission control signal EM1, a second emission control line ECL2 transmitting a second emission control signal EM2, and a data line DL transmitting the data voltage Vdata. In addition, the subpixel SPX may be further connected to a first power line VDL transmitting a first driving voltage ELVDD (e.g., a first pixel voltage of a high potential), a second power line VSL transmitting a second driving voltage ELVSS (e.g., a second pixel voltage of a low potential), an initialization power line VIL transmitting an initialization voltage VINT, and a reference power line VRL transmitting a reference voltage VREF. The subpixel SPX may be electrically connected to the power supply unit 700 through the power lines PL. Various modifications may be made in the types and number of signal lines and power lines PL, which are connected to the subpixel SPX, depending on the structure or operation mode of the subpixel SPX.

The pixel circuit PXC may include a plurality of transistors including a driving transistor DT and at least one switching transistor, and at least one capacitor C. In one or more embodiments, the pixel circuit PXC includes a first transistor T1 as the driving transistor DT of the subpixel SPX, and may include a second transistor T2, a third transistor T3, a fourth transistor T4, a fifth transistor T5, and a sixth transistor T6 as switching transistors of the subpixel SPX. In one or more embodiments, the pixel circuit PXC may include a first capacitor C1 and a second capacitor C2.

In one or more embodiments, the subpixel SPX may include different types of transistors. For example, the subpixel SPX may include at least one P-type transistor and at least one N-type transistor. For example, the fifth transistor T5 of the first to sixth transistors T1 to T6 of the subpixel SPX may be a P-type transistor, and the first, second, third, fourth, and sixth transistors T1, T2, T3, T4, and T6 may be N-type transistors. Alternatively, the fifth and sixth transistors T5 and T6 of the first to sixth transistors T1 to T6 of the subpixel SPX may be P-type transistors, and the first, second, third, and fourth transistors T1, T2, T3, and T4 thereof may be N-type transistors.

In one or more embodiments, the P-type transistor included in the subpixel SPX may be a polycrystalline silicon transistor including an active layer containing polycrystalline silicon (e.g., low-temperature polycrystalline silicon formed in a low-temperature process), and the N-type transistor included in the subpixel SPX may be an oxide transistor including an active layer containing an oxide semiconductor. In one or more embodiments, the active layer (e.g., the active layer containing polycrystalline silicon) of the P-type transistor and the active layer (the active layer containing an oxide semiconductor) of the N-type transistor may be arranged on different layers inside the display panel 100.

In describing the embodiments, the first transistor T1 may be referred to as “a driving transistor DT”. At least one switching transistor including the same type of semiconductor material (e.g., oxide semiconductor) as that of the first transistor T1 among the switching transistors (e.g., second to sixth transistors T2 to T6), for example, each of the second, third, fourth and sixth transistors T2, T3, T4, and T6 may be referred to as “a first switching transistor ST1”. Active layers of the first transistor T1 and the first switching transistors ST1 may be formed concurrently (e.g., simultaneously). At least one switching transistor including a semiconductor material (e.g., polycrystalline silicon) different from that of the first transistor T1, for example, the fifth transistor T5 may be referred to as “a second switching transistor ST2”.

The first transistor T1 may include a gate electrode electrically connected to a first node N1, a drain electrode (or a drain region) electrically connected to a second node N2, and a source electrode (or a source region) electrically connected to a third node N3. The first transistor T1 may control the driving current Id flowing through the subpixel SPX in response to a voltage (e.g., a voltage corresponding to the data voltage Vdata) applied to the first node N1.

According to one or more embodiments, when the first transistor T1 is formed as an oxide transistor including an oxide semiconductor, a rate of change of a source-drain current (e.g., the driving current Id flowing through the subpixel SPX) of the first transistor T1 according to a gate-source voltage may be relatively high compared to the case that the first transistor T1 is formed as a transistor including low-temperature polycrystalline silicon. For example, in a low gray level area where the first transistor T1 is weakly turned on (e.g., the first transistor T1 is turned on to produce a small driving current Id) so that a small driving current Id flows through the first transistor T1, sensitivity of a current-voltage change of the first transistor T1 is high, and thus it may be difficult to accurately or uniformly adjust the driving current Id flowing through each subpixel SPX. Accordingly, a luminance deviation of the subpixels SPX may occur, thereby causing image quality defects such as spots (e.g., low gray level spots occurring in portions expressing a low gray level) that are visually recognized in the image.

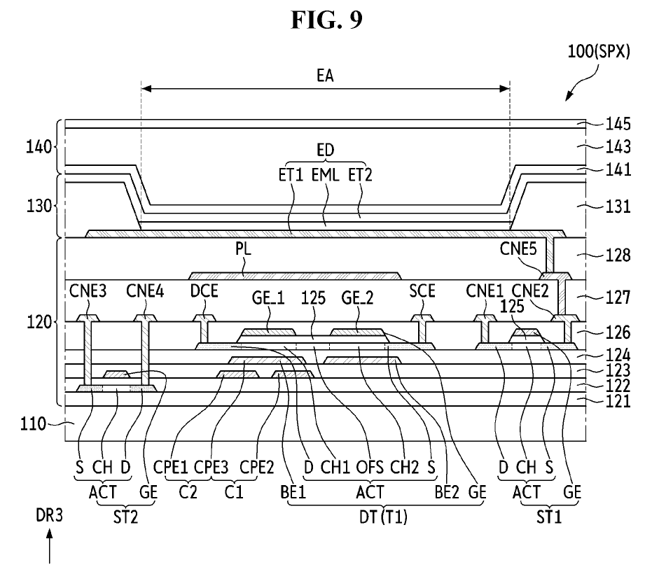

To solve the above problem, in one or more embodiments, at least one bottom electrode is formed in the first transistor T1, and characteristics of the first transistor T1 may be adjusted or improved by using the bottom electrode. For example, the first transistor T1 may include a plurality of channel regions overlapping different portions of the gate electrode, and a plurality of bottom electrodes facing the gate electrode with each of the plurality of channel regions therebetween (e.g., see FIG. 9). The channel region is interposed between the bottom electrode and the gate electrode (e.g., see FIG. 9). For example, the first transistor T1 may further include a first bottom electrode BE1 arranged below the first channel region adjacent to the drain electrode (or the drain region), and a second bottom electrode BE2 arranged below the second channel region adjacent to the source electrode (or the source region) (e.g., see FIG. 9).

In one or more embodiments, the first bottom electrode BE1 may be electrically connected to the source electrode (or the source region) of the first transistor T1, and the second bottom electrode BE2 may be electrically connected to the gate electrode of the first transistor T1. For example, the first bottom electrode BE1 may be electrically connected to the third node N3, and the second bottom electrode BE2 may be electrically connected to the first node N1.

Accordingly, a data swing range (DSR) may be reduced by increasing an on-current of the first transistor T1 while making sure of a subthreshold slope SS of the first transistor T1 (e.g., a suitable subthreshold slope SS of the first transistor T1 may be ensured or maintained). For example, the subthreshold slope of the first transistor T1 may be increased by the first bottom electrode BE1, so that the first transistor T1 is weakly turned on and thus sensitivity of the current-voltage change of the first transistor T1 is reduced for a period at which a small driving current Id flows (e.g., a period at which the subpixel SPX emits light with low luminance by the data voltage Vdata corresponding to a low gray level), whereby the driving current Id flowing through the subpixel SPX may be adjusted more uniformly and/or finely. Furthermore, the on-current of the first transistor T1 may be increased by the second bottom electrode BE2, so that the data voltage swing range (DSR) suitable for driving the first transistor T1 may be reduced for a period at which a larger driving current Id flows through the first transistor T1 (e.g., a period at which the subpixel SPX emits light with high luminance by the data voltage Vdata corresponding to a high gray level). As a result, image quality and power consumption of the display panel 100 may be improved.

The second transistor T2 may include a gate electrode electrically connected to the first gate line GWL, a drain electrode (or a drain region) electrically connected to the data line DL, and a source electrode (or a source region) electrically connected to the first node N1. The second transistor T2 may be turned on by the first gate signal GW (e.g., a first gate signal GW of a gate-on voltage corresponding to high level) transmitted to the first gate line GWL to electrically connect the data line DL with the first node N1. When the second transistor T2 is turned on, the data voltage Vdata applied to the data line DL may be transmitted to the first node N1.

The third transistor T3 may include a gate electrode electrically connected to the third gate line GRL, a drain electrode (or a drain region) electrically connected to the reference power line VRL, and a source electrode (or a source region) electrically connected to the first node N1. The third transistor T3 may be turned on by the third gate signal GR (e.g., a third gate signal GR of a gate-on voltage corresponding to a high level) transmitted to the third gate line GRL to transmit the reference voltage VREF applied to the reference power line VRL to the first node N1.

The fourth transistor T4 may include a gate electrode electrically connected to the second gate line GIL, a drain electrode (or a drain region) electrically connected to a fourth node N4, and a source electrode (or a source region) electrically connected to the initialization power line VIL. The fourth transistor T4 may be turned on by the second gate signal GIN transmitted to the second gate line GIL. When the fourth transistor T4 is turned on, a voltage of the fourth node N4 may be initialized to the initialization voltage VINT applied to the initialization power line VIL.

The fifth transistor T5 may include a gate electrode electrically connected to the first emission control line ECL1, a first electrode (e.g., a source electrode or a source region) electrically connected to the first power line VDL, and a second electrode (e.g., a drain electrode or a drain region) electrically connected to the second node N2. The fifth transistor T5 may be turned on by the first emission control signal EM1 (e.g., the first emission control signal EM1 of a gate-on voltage corresponding to low level) transmitted to the first emission control line ECL1 to electrically connect the first power line VDL with the first transistor T1.

The sixth transistor T6 may include a gate electrode electrically connected to the second emission control line ECL2, a drain electrode (or a drain region) electrically connected to the third node N3, and a source electrode (or a source region) electrically connected to the fourth node N4. The sixth transistor T6 may be turned on by the second emission control signal EM2 (e.g., the second emission control signal EM2 of a gate-on voltage corresponding to high level) transmitted to the second emission control line ECL2 to electrically connect the first transistor T1 with the light emitting element ED.

In one or more embodiments, the first emission control signal EM1 and the second emission control signal EM2 are individually supplied to the gate electrode of the fifth transistor T5 and the gate electrode of the sixth transistor T6, respectively, so that driving of the fifth transistor T5 and the sixth transistor T6 may be independently controlled. For example, during a compensation period for compensating for the characteristics of the subpixel SPX, the fifth transistor T5 may be turned on and the sixth transistor T6 may be turned off. During a light emission period of the subpixel SPX, both the fifth transistor T5 and the sixth transistor T6 may be turned on by the first light emission control signal EM1 and the second light emission control signal EM2. Accordingly, the driving current Id may flow through the subpixel SPX.

The first capacitor C1 may be electrically connected between the first node N1 and the third node N3. The first capacitor C1 is a storage capacitor of the subpixel SPX, and may store a voltage corresponding to the data voltage Vdata.

The second capacitor C2 may be electrically connected between the first power line VDL and the third node N3. The second capacitor C2 is a hold capacitor of the subpixel SPX, and may serve to stabilize operating characteristics of the subpixel SPX.

The light emitting element ED may be electrically connected between the fourth node N4 and the second power line VSL. For example, the light emitting element ED may include a first electrode (e.g., an anode electrode) electrically connected to the fourth node N4, a second electrode (e.g., a cathode electrode) facing the first electrode, connected to the second power line VSL, and a light emitting layer interposed between the first electrode and the second electrode. In one or more embodiments, the first electrode of the light emitting element ED may be a pixel electrode individually arranged in each subpixel SPX, and the second electrode of the light emitting element ED may be a common electrode shared by the plurality of pixels PX. The light emitting element ED may emit light with luminance corresponding to the driving current Id during a period at which the driving current Id flows through the subpixel SPX. The light emitting element ED may emit light of a specific color (e.g., red light, green light, blue light, or white light).

In one or more embodiments, the light emitting element ED may be an organic light emitting diode (OLED) including an organic light emitting layer, but is not limited thereto. For example, the light emitting element ED may be another type of light emitting element such as a quantum dot LED including a quantum dot light emitting layer, an inorganic LED including an inorganic semiconductor, a micro LED, or a nano LED.

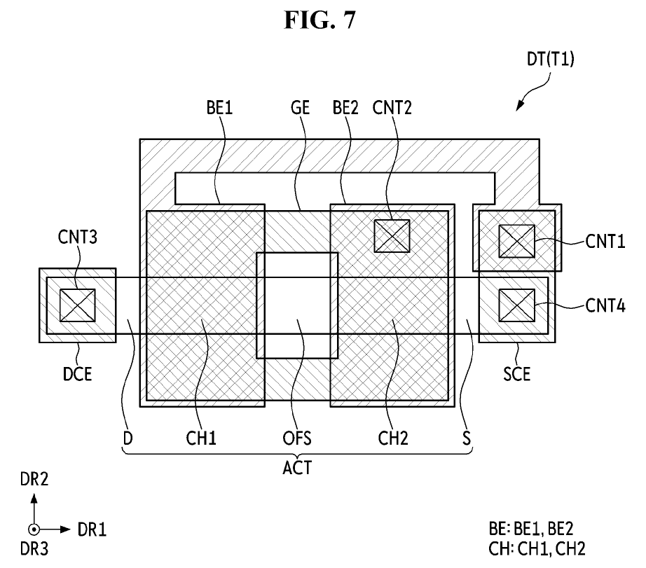

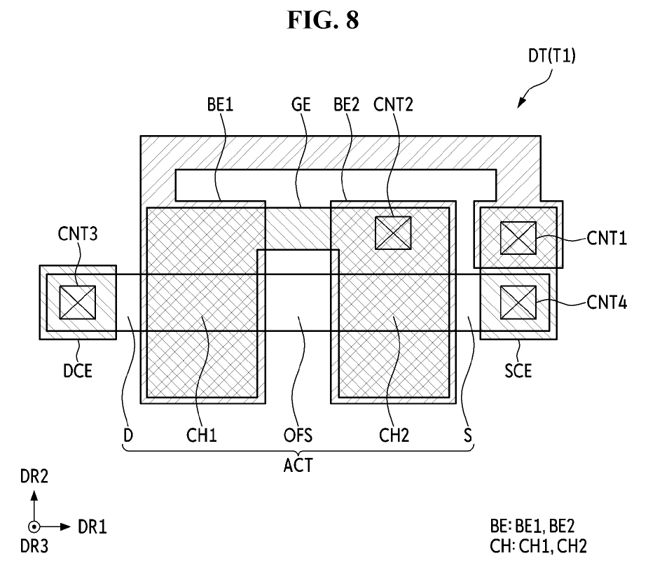

FIG. 7 is a plan view illustrating a driving transistor of a subpixel according to one or more embodiments. FIG. 8 is a plan view illustrating a driving transistor of a subpixel according to one or more embodiments. For example, FIGS. 7 and 8 are plan views schematically illustrating a first transistor T1 of FIG. 6, which show different embodiments in relation to the shape of the gate electrode GE.

Referring to FIGS. 7 and 8 in addition to FIG. 6, the driving transistor DT of the subpixel SPX according to one or more embodiments may include a plurality of channel regions CH and a plurality of bottom electrodes BE. For example, the driving transistor DT may include first and second channel regions CH1 and CH2 and first and second bottom electrodes BE1 and BE2.

In detail, the driving transistor DT may include an active layer ACT including channel regions CH, and gate electrodes GE and bottom electrodes BE, which overlap the channel regions CH. In one or more embodiments, the bottom electrodes BEs may be arranged below the active layer ACT, and the gate electrode GE may be arranged above the active layer ACT.

FIG. 9 illustrates that the active layer ACT has a rectangular planar shape extending in the first direction DR1. However, various modifications may be made in the shape and/or the extension direction of the active layer ACT depending on the embodiments.

The active layer ACT may include a first channel region CH1, a second channel region CH2, a drain region D, and a source region S. In one or more embodiments, the active layer ACT may further include an offset region OFS between the first channel region CH1 and the second channel region CH2. In one or more embodiments, the first channel region CH1, the second channel region CH2, and the offset region OFS may be first semiconductor areas (e.g., semiconductor areas including a low concentration carrier) having relatively low conductivity, and may be areas that maintain semiconductor properties without being doped. The drain region D and the source region S may be second semiconductor areas (e.g., electrode areas including a high concentration carrier) having higher conductivity than the first semiconductor area.

The first channel region CH1 and the second channel region CH2 may overlap different portions of the gate electrode GE. For example, the first channel region CH1 may overlap a first portion (e.g., GE_1 of FIG. 9) of the gate electrode GE, which is adjacent to the drain region D, and the second channel region CH2 may overlap a second portion (e.g., GE_2 of FIG. 9) of the gate electrode GE, which is adjacent to the source region S. In addition, the first channel region CH1 may overlap the first bottom electrode BE1, and the second channel region CH2 may overlap the second bottom electrode BE2. For example, in the third direction DR3, the first channel region CH1 may be arranged between the first bottom electrode BE1 and the first portion (e.g., GE_1 of FIG. 9) of the gate electrode GE, and the second channel region CH2 may be arranged between the second bottom electrode BE2 and the second portion (e.g., GE_2 of FIG. 9) of the gate electrode GE.

The gate electrode GE may overlap a portion of the active layer ACT. For example, the gate electrode GE includes a first portion (e.g., GE_1 of FIG. 9) and a second portion(e.g., GE_2 of FIG. 9), which cover the first channel region CH1 and the second channel region CH2, respectively, and may not cover the drain region D, the source region S, and the offset region OFS. In one or more embodiments, the first portion (e.g., GE_1 of FIG. 9) and the second portion (e.g., GE_2 of FIG. 9) of the gate electrode GE may be integrally formed, and may be connected to each other at a portion that does not overlap the active layer ACT. For example, the first portion (e.g., GE_1 of FIG. 9) and the second portion (e.g., GE_2 of FIG. 9) of the gate electrode GE may be connected to each other around the offset region OFS. The offset region OFS may act as a resistance component.

In one or more embodiments, the gate electrode GE may have a closed planar shape as shown in FIG. 7 or an open planar shape as shown in FIG. 8. Various modifications may be made in the shape or size of the gate electrode GE depending on the embodiments.

The first bottom electrode BE1 may be electrically connected to the source region S. For example, the first bottom electrode BE1 may be electrically connected to a source connection electrode SCE through a first contact hole CNT1, and may be electrically connected to the source region SCE through the source connection electrode SCE.

The second bottom electrode BE2 may be electrically connected to the gate electrode GE. For example, the second bottom electrode BE2 and the gate electrode GE may be electrically connected to each other through a second contact hole CNT2 at a portion that does not overlap the active layer ACT. Alternatively, the second bottom electrode BE2 and the gate electrode GE may be electrically connected to each other through a connection electrode.

In one or more embodiments, the first bottom electrode BE1 and the second bottom electrode BE2 may be arranged on (e.g., at) the same layer. For example, the first bottom electrode BE1 and the second bottom electrode BE2 may be arranged to be spaced (e.g., spaced apart) from each other on one conductive layer arranged below the active layer ACT of the driving transistor DT among the conductive layers included in the backplane layer 120, but the present disclosure is not limited thereto. For example, the first bottom electrode BE1 and the second bottom electrode BE2 may be arranged on different conductive layers among the conductive layers included in the backplane layer 120. In this case, the first bottom electrode BE1 and the second bottom electrode BE2 may overlap or may not overlap each other. The characteristics of the driving transistor DT may be adjusted by adjusting the position and size of each of the first bottom electrode BE1 and the second bottom electrode BE2, and/or a distance and/or an overlap area between each of the first and second bottom electrodes BE1 and BE2 and the active layer ACT.

The driving transistor DT may be electrically connected to other circuit elements, lines, and/or connection electrodes. For example, the drain region D of the driving transistor DT may be electrically connected to a drain connection electrode DCE through a third contact hole CNT3, and the source region S of the driving transistor DT may be electrically connected to the source connection electrode SCE through a fourth contact hole CNT4.

The drain connection electrode DCE may be regarded as a connection electrode electrically connected to the driving transistor DT, or may be regarded as an electrode (e.g., a drain electrode of the driving transistor DT) included in the driving transistor DT. The source connection electrode SCE may be regarded as a connection electrode electrically connected to the driving transistor DT, or may be regarded as an electrode (e.g., a source electrode of the driving transistor DT) included in the driving transistor DT.

The shapes and/or sizes of the drain connection electrode DCE and the source connection electrode SCE are not limited to those illustrated in FIGS. 7 and 8, and may be variously changed depending on embodiments.

FIG. 9 is a cross-sectional view illustrating a display panel according to one or more embodiments. For example, FIG. 9 schematically shows a cross-section of the display panel 100 for a portion of the display area DA including a portion of one subpixel SPX.

Referring to FIGS. 1 – 9, the display panel 100 may include a substrate 110, a backplane layer 120 arranged on the substrate 110, a light emitting element layer 130, and an encapsulation layer 140. In one or more embodiments, the display panel 100 may further include at least one of the touch sensing layer 150 or the optical layer 160 of FIG. 4.

The substrate 110 is a base member for forming the display panel 100, and may include a single layer or multi-layer. In one or more embodiments, the substrate 110 may include a flexible material such as a polymer resin, and may be a flexible substrate that may be subjected to modification such as bending, folding, rolling, and/or the like, but the present disclosure is not limited thereto. For example, the substrate 110 may be a rigid substrate that includes a rigid material such as glass.

The substrate 110 may include a display area DA and a non-display area NDA. The display area DA may include pixel areas in which pixels PX are arranged. Each pixel area may include pixel circuit areas in which circuit elements included in the pixel circuits PXC of the subpixels SPX are arranged, and light emission areas EA in which light emitting elements ED of the subpixels SPX are arranged.

In one or more embodiments, the pixel circuit area and the light emission area EA of each subpixel SPX may overlap each other in the third direction DR3 (e.g., a thickness direction of the substrate 110). For example, the light emitting element ED of each subpixel SPX may be arranged on the circuit elements included in the pixel circuit PXC of each subpixel SPX. When the pixel circuit PXC and the light emitting element ED of each subpixel SPX may be electrically connected to each other, a mutual arrangement structure of the pixel circuit area and the light emission area EA is not limited thereto.

The backplane layer 120 may include circuit elements included in the pixel circuits PXC of the subpixels SPX and lines electrically connected to the subpixels SPX. For example, the backplane layer 120 may include the first to sixth transistors T1 to T6, the first capacitor C1, the second capacitor C2, the gate lines GL, the data line DL and the power lines PL of FIG. 6.

FIG. 9 shows the driving transistor DT (e.g., the first transistor T1 of FIGS. 6 – 8), the first switching transistor ST1 (e.g., the sixth transistor T6 of FIG. 6), the second switching transistor ST2 (e.g., the fifth transistor T5 of FIG. 6), the first capacitor C1, and the second capacitor C2, which are included in one pixel circuit PXC, as examples of circuit elements that may be included in the backplane layer 120. Each of the driving transistor DT, the first switching transistor ST1, and the second switching transistor ST2 may include an active layer ACT and a gate electrode GE. In addition, each of the driving transistor DT, the first switching transistor ST1, and the second switching transistor ST2 may selectively further include a source electrode and/or a drain electrode.

Also, FIG. 9 shows one power line PL as an example of lines that may be included in the backplane layer 120. For example, the power line PL of FIG. 9 may be one of the power lines PL electrically connected to the subpixel SPX of FIG. 9. Although FIG. 9 illustrates an embodiment in which the power line PL is arranged on the circuit elements of the backplane layer 120, various modifications may be made in the position or structure of each line depending on embodiments.

The backplane layer 120 may include at least one semiconductor layer, a plurality of conductive layers, and insulating layers. In one or more embodiments, when the circuit elements of the backplane layer 120 include at least two types of transistors including different semiconductor materials, the backplane layer 120 may include a plurality of semiconductor layers. For example, the backplane layer 120 may include a first semiconductor layer including an active layer ACT containing polycrystalline silicon, and a second semiconductor layer including an active layer ACT containing an oxide semiconductor.

In detail, a buffer layer 121 may be arranged on the substrate 110. The buffer layer 121 may include a material (e.g., silicon nitride (SiNx), silicon oxide (SiOx), silicon oxynitride (SiON), titanium oxide (TiOx), aluminum oxide (AlOx), or other inorganic insulating material) suitable for protecting the circuit elements of the backplane layer 120 and the light emitting elements ED on the backplane layer 120 from moisture permeated through the substrate 110 vulnerable to moisture permeation. The buffer layer 121 may be formed as a single layer or multi-layer.

The first semiconductor layer including a first semiconductor material (e.g., polycrystalline silicon) may be arranged on the buffer layer 121. The first semiconductor layer may include an active layer ACT of the second switching transistor ST2.

The active layer ACT of the second switching transistor ST2 may include a channel region CH, and a source region S and a drain region D, which are arranged on different sides of the channel region CH. According to one or more embodiments, at least one transistor included in each subpixel SPX may be formed using polycrystalline silicon, so that power consumption of the display device 1 may be reduced.

A first insulating layer 122 may be arranged on the first semiconductor layer. For example, the first insulating layer 122 may be arranged on the buffer layer 121 to cover patterns of the first semiconductor layer including the active layer ACT of the second switching transistor ST2. The first insulating layer 122 includes at least one insulating material (e.g., an inorganic insulating material), and may be formed as a single layer or multi-layer.

A first conductive layer (e.g., a first gate metal layer) including a conductive material may be arranged on the first insulating layer 122. The first conductive layer may include a gate electrode GE of the second switching transistor ST2. In one or more embodiments, the first conductive layer may further include a first capacitor electrode CPE1 and a second capacitor electrode CPE2. Patterns of the first conductive layer including the gate electrode GE of the second switching transistor ST2, the first capacitor electrode CPE1, and the second capacitor electrode CPE2 may be formed concurrently (e.g., simultaneously) using the same material.

A second insulating layer 123 may be arranged on the first conductive layer and on the first insulating layer 122. The second insulating layer 123 includes at least one insulating material (e.g., an inorganic insulating material), and may be formed as a single layer or multi-layer.

A second conductive layer (e.g., a second gate metal layer) including a conductive material may be arranged on the second insulating layer 123. The second conductive layer may include a first bottom electrode BE1 and a second bottom electrode BE2 of the driving transistor DT.

The first bottom electrode BE1 is arranged below the first channel region CH1 of the driving transistor DT, and may overlap a first portion GE_1 of the gate electrode GE included in the driving transistor DT. As shown in FIGS. 6 – 8, the first bottom electrode BE1 may be electrically connected to the source region S of the driving transistor DT.

The second bottom electrode BE2 is arranged below the second channel region CH2 of the driving transistor DT, and may overlap a second portion GE_2 of the gate electrode GE included in the driving transistor DT. The second bottom electrode BE2 may be electrically connected to the gate electrode GE of the driving transistor DT as shown in FIGS. 6 – 8.

In one or more embodiments, at least one of the first bottom electrode BE1 or the second bottom electrode BE2 may also function as a capacitor electrode. For example, the first bottom electrode BE1 overlaps the first capacitor electrode CPE1 and the second capacitor electrode CPE2, and may also function as a third capacitor electrode CPE3.

At least one capacitor C may be formed using the first capacitor electrode CPE1, the second capacitor electrode CPE2, and the third capacitor electrode CPE3. For example, capacitance may be formed between the first capacitor electrode CPE1 and the third capacitor electrode CPE3, and between the second capacitor electrode CPE2 and the third capacitor electrode CPE3, and the first capacitor C1 and the second capacitor C2 may be formed by the capacitance. For example, the first capacitor electrode CPE1 may be electrically connected to the first power line VDL, and the second capacitor C2 may be formed by the first capacitor electrode CPE1 and the third capacitor electrode CPE3. The second capacitor electrode CPE2 may be electrically connected to the gate electrode GE of the driving transistor DT, and the first capacitor C1 may be formed by the second capacitor electrode CPE2 and the third capacitor electrode CPE3.

A third insulating layer 124 may be arranged on the second conductive layer and on the second insulating layer 123. The third insulating layer 124 includes at least one insulating material (e.g., an inorganic insulating material), and may be formed as a single layer or multi-layer.

A second semiconductor layer including a second semiconductor material may be arranged on the third insulating layer 124. In one or more embodiments, the second semiconductor material may be at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or other oxide semiconductor.

The second semiconductor layer may include an active layer ACT of the driving transistor DT and an active layer ACT of the first switching transistor ST1. The active layer ACT of the driving transistor DT and the active layer ACT of the first switching transistor ST1 may be formed concurrently (e.g., simultaneously) using the same material (e.g., the same oxide semiconductor).

The active layer ACT of the driving transistor DT may include a first channel region CH1, a second channel region CH2, a drain region D arranged on one side of the first channel region CH1, a source region S arranged on one side of the second channel region CH2, and an offset region OFS arranged between the first channel region CH1 and the second channel region CH2.

The active layer ACT of the first switching transistor ST1 may include a channel region CH, and a drain region D and a source region S, which are arranged on different sides of the channel region CH. According to one or more embodiments, at least one transistor including the driving transistor DT of each subpixel SPX is formed using an oxide semiconductor, so that leakage current of the subpixels SPX may be reduced and operating characteristics of the subpixels SPX may be improved.

The gate insulating layer 125 may be arranged on the second semiconductor layer. The gate insulating layer 125 includes at least one insulating material (e.g., an inorganic insulating material), and may be formed as a single layer or multi-layer.

In one or more embodiments, the gate insulating layer 125 may have a shape and/or a size corresponding to the gate electrode GE of each of the driving transistor DT and the first switching transistor ST1, and may be partially arranged only on a portion (e.g., the channel regions CH and the offset region OFS of the driving transistor DT and the channel region CH of the first switching transistor ST1) of the active layer ACT included in each of the driving transistor DT and the first switching transistor ST1. For example, the gate insulating layer 125 may be formed entirely in the display area DA and/or the like, and then may be etched to have a shape and/or a size corresponding to the gate electrode GE of each of the driving transistor DT and the first switching transistor ST1, but the present disclosure is not limited thereto. The gate insulating layer 125 may be formed entirely in the display area DA.

A third conductive layer (e.g., a third gate metal layer) including a conductive material may be arranged on the gate insulating layer 125. The third conductive layer may include a gate electrode GE of each of the driving transistor DT and the first switching transistor ST1.

A fourth insulating layer 126 may be arranged on the third conductive layer and on the third insulating layer 124. The fourth insulating layer 126 includes at least one insulating material (e.g., an inorganic insulating material), and may be formed as a single layer or multi-layer. The fourth insulating layer 126 may also be referred to as “an interlayer insulating layer”.

A fourth conductive layer (e.g., a first source-drain metal layer) including a conductive material may be arranged on the fourth insulating layer 126. The fourth conductive layer may include connection electrodes electrically connected to the circuit elements of the backplane layer 120. For example, the fourth conductive layer may include a drain connection electrode DCE and a source connection electrode SCE, which are electrically connected to the driving transistor DT, a first connection electrode CNE1 and a second connection electrode CNE1, which are electrically connected to the first switching transistor ST1, and a third connection electrode CNE3 and a fourth connection electrode CNE4, which are electrically connected to the second switching transistor ST2.

The drain connection electrode DCE may be electrically connected to the drain region D of the driving transistor DT through a contact hole (e.g., the third contact hole CNT3 of FIG. 7 or FIG. 8) passing through the fourth insulating layer 126. In a case where the driving transistor DT of FIG. 9 is the first transistor T1 of FIG. 6, the drain connection electrode DCE may be electrically connected to the second node N2.

The source connection electrode SCE may be electrically connected to the source region S of the driving transistor DT through a contact hole (e.g., the fourth contact hole CNT4 of FIG. 7 or 8) passing through the fourth insulating layer 126. In a case where the driving transistor DT of FIG. 9 is the first transistor T1 of FIG. 6, the source connection electrode SCE may be electrically connected to the third node N3.

The first connection electrode CNE1 may be electrically connected to the drain region D of the first switching transistor ST1 through a contact hole passing through the fourth insulating layer 126. When the first switching transistor ST1 of FIG. 9 is the sixth transistor T6 of FIG. 6, the first connection electrode CNE1 may be electrically connected to the third node N3. In this case, the first connection electrode CNE1 and the source connection electrode SCE may be formed to be connected to each other. In one or more embodiments, when the driving transistor DT and the first switching transistor ST1 of FIG. 9 are the first and sixth transistors T1 and T6 of FIG. 6, respectively, the source region S of the driving transistor DT and the drain region D of the first switching transistor ST1 may be integrally formed. In this case, the first connection electrode CNE1 may be omitted.

The second connection electrode CNE2 may be electrically connected to the source region S of the first switching transistor ST1 through the contact hole passing through the fourth insulating layer 126. When the first switching transistor ST1 of FIG. 9 is the sixth transistor T6 of FIG. 6, the second connection electrode CNE2 may be electrically connected to the light emitting element ED. For example, the second connection electrode CNE2 may be electrically connected to the first electrode ET1 of the light emitting element ED through a fifth connection electrode CNE5.

The third connection electrode CNE3 may be electrically connected to the source region S of the second switching transistor ST2 through a contact hole passing through the first, second, third, and fourth insulating layers 122, 123, 124, and 126. When the second switching transistor ST2 of FIG. 9 is the fifth transistor T5 of FIG. 6, the third connection electrode CNE3 may be electrically connected to the first power line VDL.

The fourth connection electrode CNE4 may be electrically connected to the drain region D of the second switching transistor ST2 through the contact hole passing through the first, second, third, and fourth insulating layers 122, 123, 124, and 126. When the second switching transistor ST2 of FIG. 9 is the fifth transistor T5 of FIG. 6, the fourth connection electrode CNE4 may be electrically connected to the second node N2. In this case, the fourth connection electrode CNE4 and the drain connection electrode DCE may be formed to be connected to each other.

A fifth insulating layer 127 may be arranged on the fourth conductive layer and on the fourth insulating layer 126. The fifth insulating layer 127 includes at least one insulating material (e.g., an acrylic resin, an epoxy resin, a phenolic resin, a polyamide resin, a polyimide resin, or other organic insulating material), and may be formed as a single layer or multi-layer. An upper surface of the fifth insulating layer 127 may be generally flat. The fifth insulating layer 127 may also be referred to as “a first planarization insulating layer”.

A fifth conductive layer (e.g., a second source-drain metal layer) including a conductive material may be arranged on the fifth insulating layer 127. The fifth conductive layer may include at least one connection electrode and/or line. For example, the fifth conductive layer may include a fifth connection electrode CNE5 electrically connected to at least one circuit element included in each of the subpixels SPX and at least one power line PL.

The fifth connection electrode CNE5 may be a conductive pattern connected between the fourth and sixth transistors T4 and T6 of FIG. 6 and the light emitting element ED. When the first switching transistor ST1 of FIG. 9 is the sixth transistor T6 of FIG. 6, the fifth connection electrode CNE5 may be electrically connected to the second connection electrode CNE2 through a contact hole passing through the fifth insulating layer 127, and may be electrically connected to the first switching transistor ST1 of FIG. 9 through the second connection electrode CNE2.

The power line PL may be one of the power lines PL electrically connected to the subpixel SPX. In one or more embodiments, the power line PL may overlap the first channel region CH1 and the second channel region CH2 of the driving transistor DT (e.g., the power line PL may overlap the first channel region CH1 and the second channel region CH2 of the driving transistor DT in the third direction DR3). Accordingly, light may be reduced or prevented from being incident on the first channel region CH1 and the second channel region CH2 of the driving transistor DT from an upper portion of the first transistor T1. Also, the first bottom electrode BE1 and the second bottom electrode BE2 may be arranged below the first channel region CH1 and the second channel region CH2 of the driving transistor DT. Accordingly, light may be reduced or prevented from being incident on the first channel region CH1 and the second channel region CH2 of the driving transistor DT from a lower portion of the driving transistor DT. Accordingly, operating characteristics of the driving transistor DT may be stabilized.

In one or more embodiments, a conductive pattern (e.g., line, electrode, etc.) that may function as a light blocking pattern may also be arranged above and/or below the channel region CH of the first switching transistor ST1. Accordingly, the operating characteristics of the first switching transistor ST1 may be stabilized.

A sixth insulating layer 128 may be arranged on the fifth conductive layer and on the fifth insulating layer 127. The sixth insulating layer 128 includes at least one insulating material (e.g., an organic insulating material), and may be formed as a single layer or multi-layer. An upper surface of the sixth insulating layer 128 may be substantially flat. The sixth insulating layer 128 may also be referred to as “a second planarization insulating layer”.

Patterns included in each of the conductive layers of the backplane layer 120 may include at least one conductive material. For example, patterns included in each of the first conductive layer on the first insulating layer 122, the second conductive layer on the second insulating layer 123, the third conductive layer on the gate insulating layer 125, the fourth conductive layer on the fourth insulating layer 126, and the fifth conductive layer on the fifth insulating layer 127 may include at least one of copper (Cu), titanium (Ti), molybdenum (Mo), aluminum (Al), chromium (Cr), gold (Au), platinum (Pt), palladium (Pd), nickel (Ni), neodymium (Nd), iridium (Ir), tantalum (Ta), tungsten (W), magnesium (Mg) or other metal, their alloy, or other conductive material. In one or more embodiments, patterns arranged on the same conductive layer may be formed concurrently (e.g., simultaneously) using the same conductive material.

In one or more embodiments, the patterns included in each of the conductive layers of the backplane layer 120 may have a single layered structure or a multi-layered structure. For example, each of the electrodes and/or lines included in the first, second, third, fourth and fifth conductive layers may have a single layered structure or a multi-layered structure.

The light emitting element layer 130 may be arranged on the sixth insulating layer 128. The light emitting element layer 130 may be positioned in the display area DA. For example, the light emitting element layer 130 may be arranged on the backplane layer 120 in the display area DA.

The light emitting element layer 130 may include the light emitting elements ED of the subpixels SPX. For example, the light emitting element layer 130 may include a pixel defining layer 131 defining the light emission area EA of each of the subpixels SPX and the light emitting element ED arranged in each light emission area EA. In one or more embodiments, the light emitting element layer 130 may further include a spacer arranged on a portion of the pixel defining layer 131.

The light emitting element ED may include a first electrode ET1, a light emitting layer EML, and a second electrode ET2, which are sequentially arranged on the backplane layer 120. For example, the first electrode ET1 of the light emitting element ED may be arranged on the sixth insulating layer 128 to correspond to each light emission area EA, and the light emitting layer EML and the second electrode ET2 may be sequentially stacked on the first electrode ET1.

In one or more embodiments, the light emitting element ED may further include at least one intermediate layer. For example, the light emitting element ED may further include a first intermediate layer (e.g., a hole injection layer and/or a hole transport layer) interposed between the first electrode ET1 and the light emitting layer EML, and a second intermediate layer (e.g., an electron transport layer) interposed between the light emitting layer EML and the second electrode ET2. In one or more embodiments, at least one intermediate layer may be a common layer formed over the entire display area DA.

The first electrode ET1 of the light emitting element ED may be electrically connected to at least one circuit element included in the corresponding subpixel SPX. For example, the first electrode ET1 of the light emitting element ED may be electrically connected to the fifth connection electrode CNE5 through the sixth insulating layer 128, and may be electrically connected to the first switching transistor ST1 (e.g., the sixth transistor T6) through the fifth connection electrode CNE5 and the second connection electrode CNE2.

The first electrode ET1 of the light emitting element ED may include at least one conductive material, and may be formed as a single layer or multi-layer. The first electrode ET1 of the light emitting element ED may be an electrode of a single layer or multi-layer including at least one conductive material. In one or more embodiments, the display panel 100 may be a top-emission display panel, and the first electrode ET1 may include a reflective electrode layer having high reflectivity.

The light emitting layer EML of the light emitting element ED includes an organic material, and may emit light of a specific color (or a specific wavelength band). For example, the light emitting layer EML may emit red light, green light, blue light, white light, or light of other color. Light emitted from the light emitting layer EML may contribute to image display.

The light emitting layer EML may be individually formed in each light emission area EA, or may be formed as a common layer over the entire display area DA. For example, the light emitting layer EML is individually arranged in the light emission area EA of each subpixel SPX, and may emit light (e.g., red light, green light, or blue light) of a color corresponding to the emission color (or emission wavelength) of each subpixel SPX. Alternatively, the light emitting layer EML is entirely arranged in the display area DA including the light emission areas EA of the subpixels SPX, and may emit light of a specific color (e.g., blue light or white light). When the light emitting layer EML emits light of a color different from the emission color (or emission wavelength) of the corresponding subpixel SPX, a light conversion layer and/or a color filter layer for converting the color (or wavelength) of light emitted from the light emitting element ED into light corresponding to the emission wavelength of the corresponding subpixel SPX may be arranged on the light emitting element ED of at least one subpixel.

The second electrode ET2 of the light emitting element ED may include a conductive material. In one or more embodiments, the second electrode ET2 of the light emitting element ED may be a common layer formed over the entire display area DA to cover the light emitting layer EML and the pixel defining layer 131. In one or more embodiments, the second electrode ET2 of the light emitting element ED may include a transparent conductive oxide (TCO) such as ITO and/or IZO, which is capable of transmitting light, or a semi-transmissive conductive material such as magnesium (Mg), silver (Ag), and/or an alloy of magnesium (Mg) and silver (Ag).

The pixel defining layer 131 has an opening corresponding to each light emission area EA, and may be around (e.g., may surround) the light emission area EA. For example, the pixel defining layer 131 may cover an edge of the first electrode ET1 of the light emitting element ED, and may include an opening for exposing another portion of the first electrode ET1. An area in which the exposed first electrode ET1 overlaps the light emitting layer EML may be defined as the light emission area EA of each subpixel SPX.

In one or more embodiments, the pixel defining layer 131 may include an organic insulating material. For example, the pixel defining layer 131 may include an acrylic resin, an epoxy resin, a phenolic resin, a polyamide resin, a polyimide resin, an unsaturated polyester resin, a polyphenylene ether resin, a polyphenylene sulfide resin, benzocyclobutene (BCB), and/or other organic insulating material.

The encapsulation layer 140 may be arranged on the light emitting element layer 130. The encapsulation layer 140 may cover the light emitting element layer 130 in the display area DA, and may extend to the non-display area NDA to be in contact with the backplane layer 120. For example, the encapsulation layer 140 may be arranged in the display area DA to cover the light emitting element layer 130, and an end of the encapsulation layer 140 may be arranged in a portion of the non-display area NDA adjacent to the display area DA. The encapsulation layer 140 may block permeation of oxygen and/or moisture into the light emitting element layer 130, and may alleviate electrical and/or physical impact on the backplane layer 120 and the light emitting element layer 130.

In one or more embodiments, the encapsulation layer 140 may be formed as a multi-layer including an inorganic encapsulation layer and an organic encapsulation layer. For example, the encapsulation layer 140 may include a first inorganic encapsulation layer 141, an organic encapsulation layer 143, and a second inorganic encapsulation layer 145, which are sequentially arranged on the light emitting element layer 130. The encapsulation layer 140 may be replaced with an encapsulation member of another type, structure, and/or material. For example, the light emitting element layer 130 may be encapsulated using an upper substrate including an insulating material such as glass, and/or a passivation layer including a capping layer of a single layer or multi-layer.

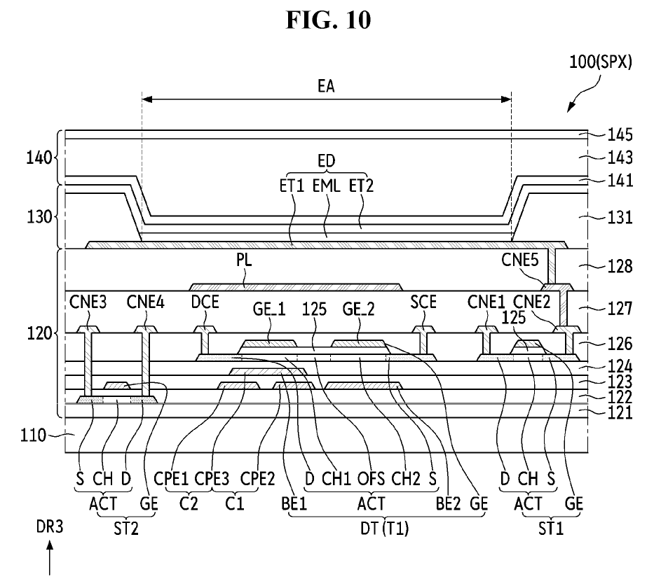

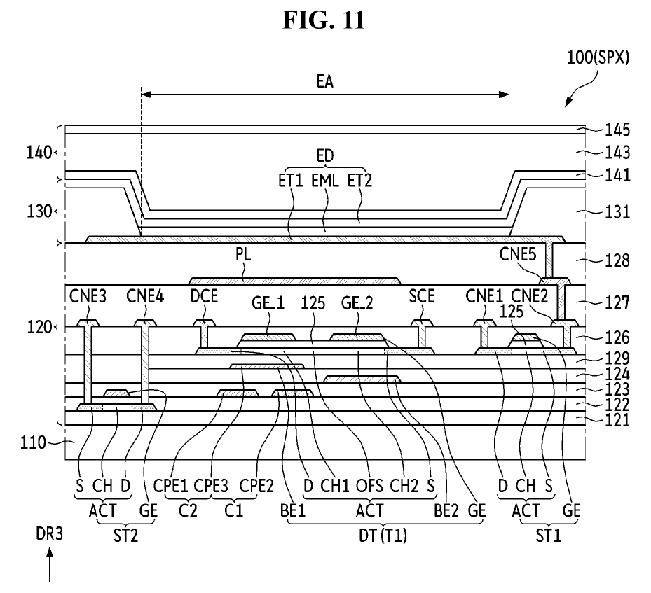

FIG. 10 is a cross-sectional view illustrating a display panel according to one or more embodiments. FIG. 11 is a cross-sectional view illustrating a display panel according to one or more embodiments. For example, FIGS. 10 and 11 illustrate different embodiments of a cross-section of the display panel 100 with respect to a portion of the display area DA including a portion of one subpixel SPX.

In comparison with FIG. 9, FIGS. 10 and 11 show embodiments in which the first bottom electrode BE1 and the second bottom electrode BE2 are arranged on layers different from each other. Each embodiment disclosed in the present disclosure may be implemented alone or in combination with at least one other embodiment. In describing the following embodiments, redundant descriptions of configurations substantially the same as or similar to those of the above-described embodiment will be omitted.

Referring to FIG. 10, the first bottom electrode BE1 is arranged on the second insulating layer 123, and may be covered by the third insulating layer 124. The second bottom electrode BE2 is arranged on the first insulating layer 122, and may be covered by the second insulating layer 123. For example, the first bottom electrode BE1 may be formed in a pattern of the second conductive layer as in the embodiment of FIG. 9, and the second bottom electrode BE2 may be formed in a pattern of the first conductive layer as in the embodiment of FIG. 9. In this case, a distance between the first bottom electrode BE1 and the first channel region CH1 may be less than a distance between the second bottom electrode BE2 and the second channel region CH2. Accordingly, it is possible to stably make sure of a subthreshold slope of the driving transistor DT (e.g., a suitable a subthreshold slope of the driving transistor DT may be ensured or maintained).

Referring to FIG. 11, the backplane layer 120 may further include an additional conductive layer and an additional insulating layer, and at least one of the first bottom electrode BE1 or the second bottom electrode BE2 may be formed in a pattern of the additional conductive layer. For example, the backplane layer 120 may further include a sixth conductive layer and a seventh insulating layer 129, which are arranged between the third insulating layer 124 and the second semiconductor layer, and the first bottom electrode BE1 may be formed in a pattern of the sixth conductive layer.

The sixth conductive layer may be arranged on the third insulating layer 124. The patterns of the sixth conductive layer including the first bottom electrode BE1 of each subpixel SPX may be covered by the seventh insulating layer 129. The second semiconductor layer including the active layer ACT of the driving transistor DT may be arranged on the sixth conductive layer and the seventh insulating layer 129.

Each of the conductive layers included in the backplane layer 120 may have a material, thickness, and/or cross-sectional structure suitable for satisfying properties required by the patterns included in each conductive layer. For example, the patterns of the conductive layer including a line may have a material, thickness, and/or cross-sectional structure suitable for reducing or minimizing RC delay of a signal or voltage applied to the line.

In one or more embodiments, the sixth conductive layer may not include a line, and patterns of the sixth conductive layer may have relatively small thicknesses compared to patterns of at least one other conductive layer (e.g., the first conductive layer on the first insulating layer 122, the second conductive layer on the second insulating layer 123, the third conductive layer on the gate insulating layer 125, the fourth conductive layer on the fourth insulating layer 126, and/or the fifth conductive layer on the fifth insulating layer 127) included in the backplane layer 120. For example, a thickness of the first bottom electrode BE1 may be less than that of the second bottom electrode BE2.

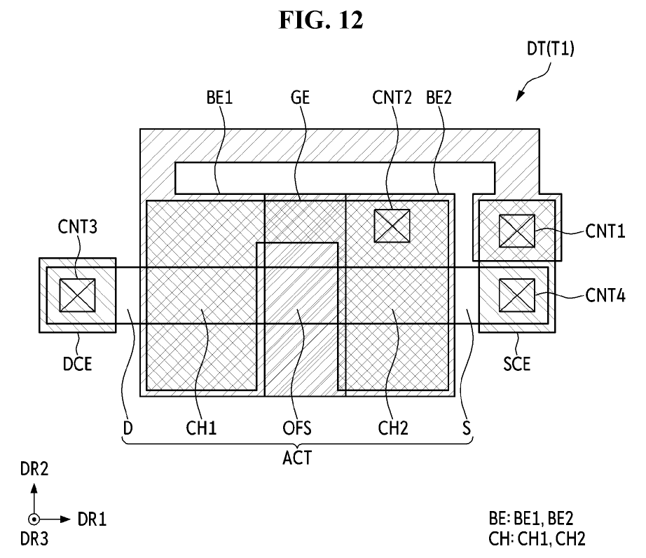

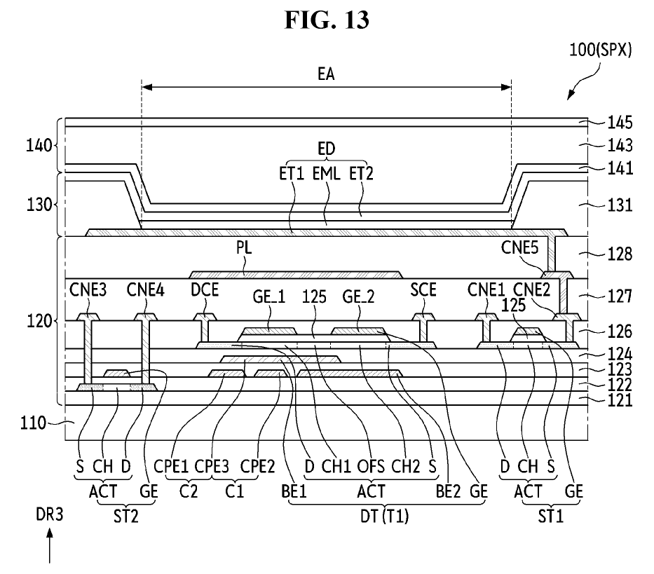

FIG. 12 is a plan view illustrating a driving transistor of a subpixel according to one or more embodiments. FIG. 13 is a cross-sectional view illustrating a display panel according to one or more embodiments. For example, FIG. 12 is a plan view schematically illustrating a first transistor T1 of FIG. 6, and FIG. 13 illustrates one embodiment of a cross-section of the display panel 100 including the driving transistor DT of FIG. 12. In comparison with FIGS. 7 – 11, FIGS. 12 and 13 show embodiments in which the mutual arrangement structure between the first bottom electrode BE1 and the second bottom electrode BE2 is changed.

Referring to FIGS. 12 and 13, the first bottom electrode BE1 and the second bottom electrode BE2 are arranged on different conductive layers of the backplane layer 120, and may overlap each other. For example, the first bottom electrode BE1 and the second bottom electrode BE2 may overlap each other below the offset region OFS of the active layer ACT.

In one or more embodiments, the first bottom electrode BE1 may be arranged on the second insulating layer 123, and the second bottom electrode BE2 may be arranged on the first insulating layer 122, but the positions of the first bottom electrode BE1 and the second bottom electrode BE2 are not limited thereto. For example, as in one embodiment of FIG. 11, the first bottom electrode BE1 may be arranged on the third insulating layer 124, and the second bottom electrode BE2 may be arranged on the second insulating layer 123.

In one or more embodiments in which the first bottom electrode BE1 and the second bottom electrode BE2 are arranged on different conductive layers, the first bottom electrode BE1 may extend below the offset region OFS, and may be arranged more adjacent to the second channel region CH2. For example, the first bottom electrode BE1 may be arranged below a boundary portion between the offset region OFS and the second channel region CH2.

According to the embodiments of FIGS. 6 – 13, the driving transistor DT may include a first channel region CH1, a second channel region CH2, and an offset region OFS arranged between the first channel region CH1 and the second channel region CH2. In one or more embodiments, the driving transistor DT may further include a first bottom electrode BE1 that overlaps the first channel region CH1 and is electrically connected to the source region S of the driving transistor DT, and a second bottom electrode BE2 that overlaps the second channel region CH2 and is electrically connected to the gate electrode GE of the driving transistor DT.

In one or more embodiments, the position and size of each of the first bottom electrode BE1 and the second bottom electrode BE2, and/or the distance and/or overlap area between each of the first bottom electrode BE1 and the second bottom electrode BE2 and the active layer ACT may be adjusted, so that the characteristics of the driving transistor DT may be adjusted in a desired direction. For example, the position or size of the first bottom electrode BE1 and the second bottom electrode BE2 may be appropriately adjusted in consideration of the subthreshold slope and on-current characteristics of the driving transistor DT, so that the characteristics of the driving transistor DT may be improved or optimized.

In one or more embodiments, the distance between each of the first bottom electrode BE1 and the second bottom electrode BE2 and the active layer ACT (e.g., the distance between the first bottom electrode BE1 and the first channel region CH1, and the distance between the second bottom electrode BE2 and the second channel region CH2) may be controlled by adjusting at least one of the position (e.g., the conductive layer in which each of the first bottom electrode BE1 and the second bottom electrode BE2 is arranged within the backplane layer 120) in which each of the first bottom electrode BE1 and the second bottom electrode BE2 is arranged or a thickness of the insulating layer interposed between each of the first bottom electrode BE1 and the second bottom electrode BE2 and the active layer ACT.

According to one or more embodiments, the operating characteristics of the driving transistor DT may be improved by making sure of the subthreshold slope of the driving transistor DT (e.g., a suitable subthreshold slope of the driving transistor DT may be ensured or maintained). Accordingly, the image quality of the display device 1 may be improved.

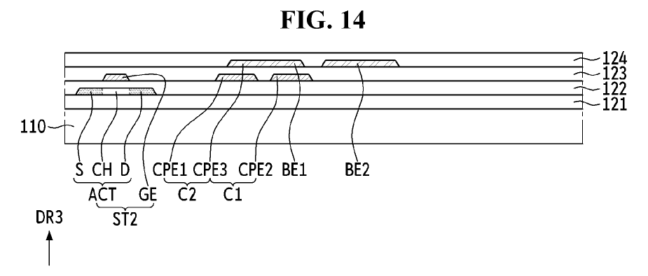

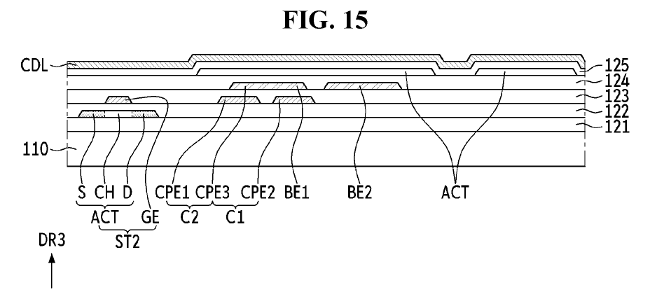

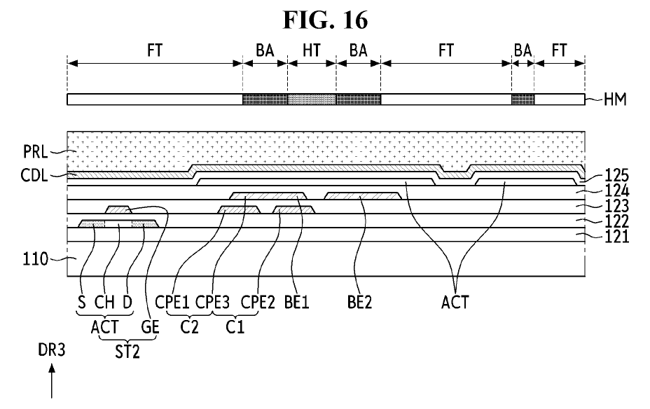

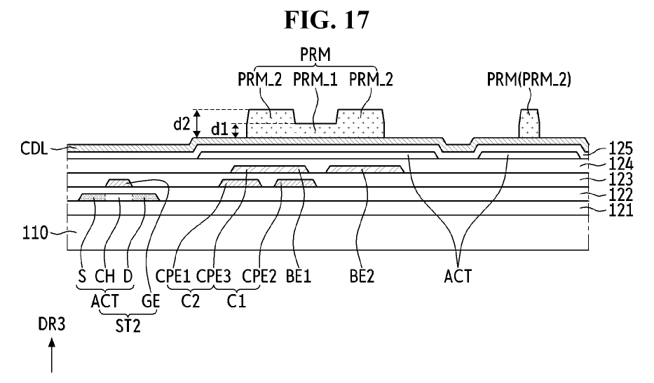

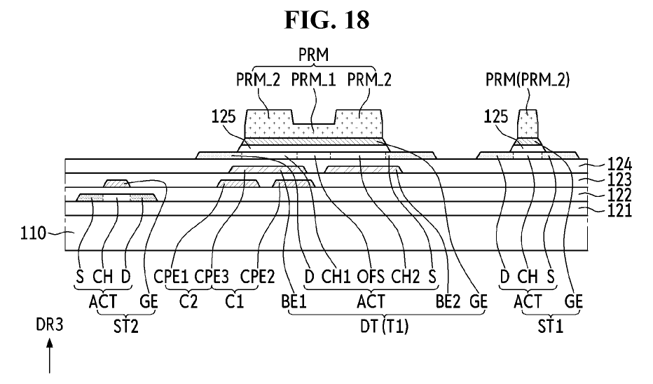

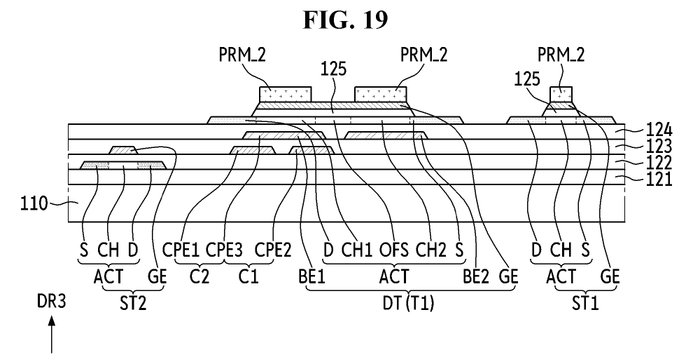

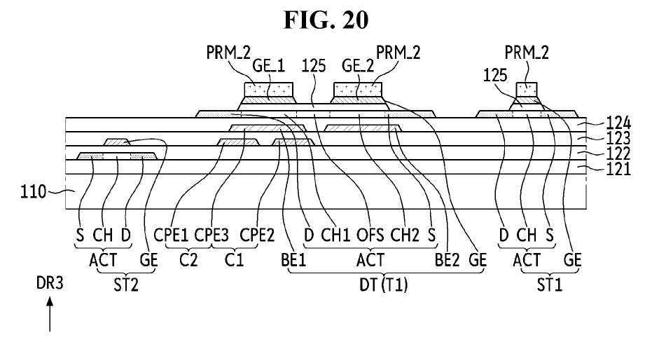

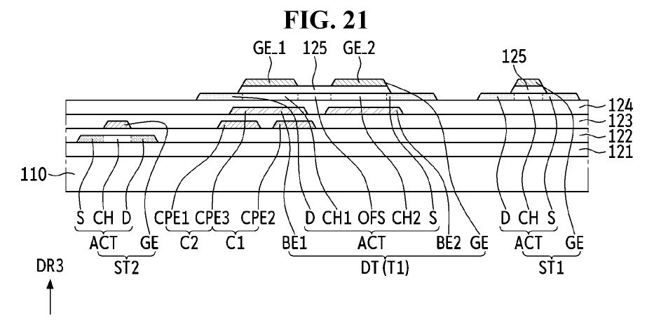

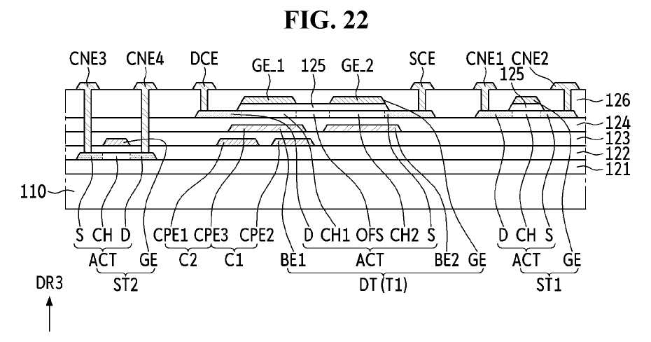

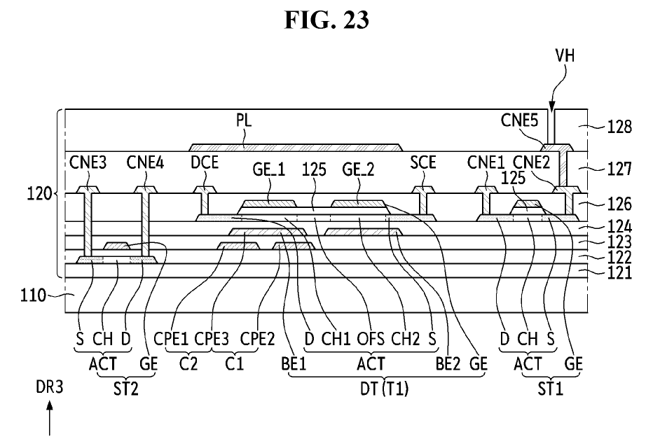

FIGS. 14 – 24 are cross-sectional views illustrating a method for manufacturing a display device according to one or more embodiments. For example, FIGS. 14 – 24 sequentially illustrate manufacturing steps of the display panel 100 including a step of forming the backplane layer 120 including the driving transistor DT according to the embodiments of FIGS. 6 – 9, and a step of forming the light emitting element layer 130 on the backplane layer 120.

However, as described above, various modifications may be made in the position, size, and/or shape of the first bottom electrode BE1 and/or the second bottom electrode BE2 depending on embodiments. For example, each of the first bottom electrode BE1 and the second bottom electrode BE2 may be formed as a pattern of one conductive layer arranged below the active layer of the driving transistor DT among the conductive layers of the backplane layer 120. In addition, the first bottom electrode BE1 and the second bottom electrode BE2 may overlap or may not overlap each other. The display panel 100 according to the embodiments of FIGS. 10 – 13 may be manufactured in a method similar to the method for manufacturing the display panel 100 according to the embodiments of FIGS. 14 – 24, except that the conductive layer on which the first bottom electrode BE1 and/or the second bottom electrode BE2 is formed is changed.

Referring to FIG. 14 in addition to FIGS. 1 – 13, the first bottom electrode BE1, the second bottom electrode BE2, and the third insulating layer 124 covering the first bottom electrode BE1 and the second bottom electrode BE2 may be formed on the substrate 110. For example, the buffer layer 121, patterns (e.g., the active layer ACT of the second switching transistor ST2) of the first semiconductor layer, the first insulating layer 122, patterns (e.g., the gate electrode GE of the second switching transistor ST2, the first capacitor electrode CPE1 and the second capacitor electrode CPE2) of the first conductive layer, the second insulating layer 123, and patterns (e.g., the first bottom electrode BE1 and the second bottom electrode BE2) of the second conductive layer, and the third insulating layer 124 may be sequentially formed on the substrate 110.

Each of the buffer layer 121, the first insulating layer 122, the second insulating layer 123, and the third insulating layer 124 may be formed by a film forming process of an insulating film including the insulating material described above. For example, each of the buffer layer 121, the first insulating layer 122, the second insulating layer 123, and the third insulating layer 124 may be formed by a deposition process of an inorganic insulating material.

The patterns of the first semiconductor layer including the active layer ACT of the second switching transistor ST2 may be formed by a film forming process of a first semiconductor film using a first semiconductor material and a patterning process of the first semiconductor film. For example, after the first semiconductor film is formed by depositing polycrystalline silicon on the buffer layer 121, the patterns of the first semiconductor layer may be formed by patterning the first semiconductor film by a photolithography process and an etching process.

Each of the patterns of the first conductive layer including the gate electrode GE of the second switching transistor ST2 and the patterns of the second conductive layer including the first bottom electrode BE1 and the second bottom electrode BE2 may be formed by a film forming process of a conductive film using a conductive material and a patterning process of the conductive film. For example, after the first conductive film is formed by depositing a conductive material on the first insulating layer 122, patterns of the first conductive layer may be formed by patterning the first conductive film by a photolithography process and an etching process. Similarly, after the second conductive film is formed by depositing a conductive material on the second insulating layer 123, patterns of the second conductive layer may be formed by patterning the second conductive film by a photolithography process and an etching process.

The first bottom electrode BE1 and the second bottom electrode BE2 may be formed in an area corresponding to an area in which the active layer ACT of the driving transistor DT is to be arranged. Also, the first bottom electrode BE1 and the second bottom electrode BE2 may be formed to be separated from (e.g., spaced from) each other.

When the second bottom electrode BE2 is formed in the pattern of the first conductive layer as in the embodiments of FIGS. 10 and 13, the second bottom electrode BE2 may be formed first in the step of forming the patterns of the first conductive layer. Afterwards, the first bottom electrode BE1 may be formed in the step of forming the patterns of the second conductive layer.

When the first bottom electrode BE1 is formed in the pattern of the sixth conductive layer on the second conductive layer as in the embodiment of FIG. 11, the second bottom electrode BE2 may be formed first in the step of forming the patterns of the second conductive layer. Afterwards, the third insulating layer 124 covering the patterns of the second conductive layer may be formed, and the first bottom electrode BE1 and the seventh insulating layer 129 may be sequentially formed on the third insulating layer 124.

Referring to FIG. 15, the patterns (e.g., the active layer ACT of the driving transistor DT and the active layer ACT of the first switching transistor ST1) of the second semiconductor layer, the gate insulating layer 125, and a third conductive film CDL may be sequentially formed on the third insulating layer 124 (or the seventh insulating layer 129 of FIG. 11).

The patterns of the second semiconductor layer including the active layer ACT of the driving transistor DT and the active layer ACT of the first switching transistor ST1 may be formed by a film forming process of a second semiconductor film using a second semiconductor material and a patterning process of the second semiconductor film. For example, after the second semiconductor film is formed by depositing an oxide semiconductor on the third insulating layer 124, the patterns of the second semiconductor layer may be formed by patterning the second semiconductor film by a photolithography process and an etching process.

The gate insulating layer 125 may be formed by a film forming process of an insulating film including the insulating material described above. For example, the gate insulating layer 125 may be formed by a deposition process of an inorganic insulating material.

The third conductive film CDL may be formed by a film forming process of a conductive film using a conductive material. For example, the third conductive film CDL may be formed by depositing a conductive material on the gate insulating layer 125.

Referring to FIGS. 16 – 21, patterns (e.g., the gate electrode GE of the driving transistor DT and the gate electrode GE of the second switching transistor ST2) of the third conductive layer may be formed by patterning the third conductive film CDL. In one or more embodiments, the gate insulating layer 125 may be etched to expose the source region S and the drain region D of each of the active layers ACT of the second semiconductor layer.

In one or more embodiments, after the patterns of the third conductive layer are formed, the source region S and the drain region D of each of the active layers ACT of the second semiconductor layer may be formed by a doping process. Alternatively, the source region S and the drain region D of each of the active layers ACT of the second semiconductor layer may be formed or defined in a different method without performing a doping process.

In detail, as shown in FIGS. 16 and 17, a photoresist material may be coated on the third conductive film CDL to form a photosensitive film (e.g., photoresist film) PRL, and a mask pattern PRM may be formed on the third conductive film CDL by a photolithography process using a halftone mask HM. For example, the mask pattern PRM may be arranged on one portion including a central portion of the active layer ACT on the active layer ACT of each of the driving transistor DT and the first switching transistor ST1, and the mask pattern PRM may not be arranged on the remaining portion including the edge portion of the active layer ACT.

The mask pattern PRM arranged on the active layer ACT of the driving transistor DT may have different thicknesses for each portion. For example, the mask pattern PRM arranged on the active layer ACT of the driving transistor DT may have a first thickness d1 in a first portion PRM_1 including a central portion, and may have a second thickness d2 greater than the first thickness d1 in a second portion PRM_2 positioned on respective sides of the first portion PRM_1. The mask pattern PRM arranged on the active layer ACT of the first switching transistor ST1 may have a thickness greater than the first thickness d1, for example, a second thickness d2.

In one or more embodiments, the mask pattern PRM may be formed to have different thicknesses for each portion by using the halftone mask HM. When the photosensitive film PRL includes a positive photoresist material, a half-tone portion HT (e.g., a translucent portion) of the halftone mask HM may be arranged on a portion of the photosensitive film PRL, which corresponds to a portion where the first portion PRM_1 of the mask pattern PRM is to be formed, and a non-tone portion BA (e.g., an opaque portion) of the halftone mask HM may be arranged on another portion of the photosensitive film PRL, which corresponds to a portion where the second portion PRM_2 of the mask pattern PRM is to be formed. Also, a full-tone portion FT (e.g., a transparent portion) of the halftone mask HM may be arranged on another portion of the photosensitive film PRL, which corresponds to a portion where the halftone mask HM will not be formed. The mask pattern PRM according to one or more embodiments may be formed by exposing the photosensitive film PRL in a state that the halftone mask HM is arranged on the photosensitive film PRL and then developing the photosensitive film PRL. For example, in a state that the halftone mask HM is arranged on the photosensitive film PRL, UV light is irradiated to the photosensitive film PRL from the top of the halftone mask HM and then the photosensitive film PRL may be developed to form the mask pattern PRM.

Afterwards, as shown in FIG. 18, the third conductive film CDL may be etched using the mask pattern PRM to form the gate electrode GE of each of the driving transistor DT and the first switching transistor ST1 below the mask pattern PRM. In one or more embodiments, the gate insulating layer 125 may be etched in a form corresponding to the gate electrode GE of each of the driving transistor DT and the first switching transistor ST1 concurrently (e.g., simultaneously) with the etching of the third conductive film CDL or after the etching of the third conductive film CDL. Accordingly, the gate insulating layer 125 may be etched in a form that exposes the source region S and the drain region D of each of the driving transistor DT and the first switching transistor ST1.

In one or more embodiments, after the third conductive film CDL is etched, the source region S and the drain region D of each of the driving transistor DT and the first switching transistor ST1 may be formed or defined. For example, the gate electrode GE of each of the driving transistor DT and the first switching transistor ST1 and a portion of each of the driving transistor DT and the first switching transistor ST1, which is not covered by the mask pattern PRM, may be formed or defined as the source region S and the drain region D.

For example, a doping process may be performed for a portion of the active layer ACT, which does not overlap the gate electrode GE of each of the driving transistor DT and the first switching transistor ST1, to form the source region S and the drain region D of each of the driving transistor DT and the first switching transistor ST1. Alternatively, the source region S and the drain region D of each of the driving transistor DT and the first switching transistor ST1 may be formed or defined without a doping process. For example, the active layers ACT of the second semiconductor layer may have a film quality change such as occurrence of a large amount of oxygen-vacancies Vo in a portion exposed by the etching process of the gate insulating layer 125. Accordingly, the active layers ACT of the second semiconductor layer may have different characteristics in a portion covered by the gate insulating layer 125 and a portion not covered by the gate insulating layer 125. In addition, conductivity of the source region S and the drain region D of each of the driving transistor DT and the first switching transistor ST1 may be enhanced by hydrogen introduced in a subsequent process.

A portion of the active layer ACT of the driving transistor DT overlapping the first portion PRM_1 of the mask pattern PRM may correspond to the offset region OFS. Another portion of the active layer ACT of the driving transistor DT overlapping the second portion PRM_2 of the mask pattern PRM may correspond to the first channel region CH1 and the second channel region CH2.

Afterwards, as shown in FIG. 19, a portion of the mask pattern PRM may be removed to expose a portion of the gate electrode GE of the driving transistor DT. For example, the first portion PRM_1 of the mask pattern PRM may be removed by performing an etch back process, so that a portion (e.g., a central portion) of the gate electrode GE of the driving transistor DT may be exposed. In this process, the thickness of the second portion PRM_2 of the mask pattern PRM may also be reduced.

Afterwards, as shown in FIG. 20, the exposed portion of the gate electrode GE of the driving transistor DT may be etched and removed. For example, a portion of the gate electrode GE of the driving transistor DT may be removed, and the first portion GE_1 and the second portion GE_2 of the gate electrode GE may be defined. A portion of the active layer ACT positioned below the first portion GE_1 of the gate electrode GE may become the first channel region CH1 of the driving transistor DT, and a portion of the active layer ACT positioned below the second portion GE_2 of the gate electrode GE may become the second channel region CH2 of the driving transistor DT. A portion of the driving transistor DT, which is arranged between the first channel region CH1 and the second channel region CH2 and is not covered by the gate electrode GE, may become the offset region OFS.

Afterwards, as shown in FIG. 21, the mask pattern PRM may be removed. For example, the mask pattern PRM may be removed from the gate electrode GE of each of the driving transistor DT and the first switching transistor ST1 by a strip process.

The driving transistor DT and the first switching transistor ST1 may be formed by the process described with reference to FIGS. 14 – 21. When the driving transistor DT further includes the drain connection electrode DCE and the source connection electrode SCE of FIG. 9 as a drain electrode and a source electrode, the driving transistor DT may be formed by forming the drain connection electrode DCE and the source connection electrode SCE through a subsequent process. Similarly, when the first switching transistor ST1 further includes the first connection electrode CNE1 and the second connection electrode CNE2 of FIG. 9 as a drain electrode and a source electrode, the first switching transistor ST1 may be formed by forming the first connection electrode CNE1 and the second connection electrode CNE2 through a subsequent process.

Referring to FIG. 22, the fourth insulating layer 126 may be formed on the driving transistor DT and the first switching transistor ST1, and the patterns (e.g., the drain connection electrode DCE and the source connection electrode SCE of the driving transistor DT and the connection electrodes CNE1, CNE2, CNE3, CNE4 electrically connected to the first switching transistor ST1 and the second switching transistor ST2) of the fourth conductive layer may be formed on the fourth insulating layer 126.

The fourth insulating layer 126 may be formed by a film forming process of an insulating film including the insulating material described above. For example, the fourth insulating layer 126 may be formed by a deposition process of an inorganic insulating material.

The patterns of the fourth conductive layer including the drain connection electrode DCE and the source connection electrode SCE of the driving transistor DT may be formed by a film forming process of the conductive film using a conductive material and a patterning process of the conductive film. For example, after the fourth conductive film is formed by depositing a conductive material on the fourth insulating layer 126, the patterns of the fourth conductive layer may be formed by patterning the fourth conductive film by a photolithography process and an etching process.

Referring to FIG. 23, patterns (e.g., the power line PL and the fifth connection electrode CNE5) of the fifth conductive layer and the sixth insulating layer 128 may be formed on the fourth insulating layer 126 and the patterns of the fourth conductive layer. A via hole VH (or a contact hole) for exposing a portion of the fifth connection electrode CNE5 may be formed in the sixth insulating layer 128.

The backplane layer 120 of the display panel 100 according to one or more embodiments may be formed by the process described with reference to FIGS. 14 – 23.

Referring to FIG. 24, the light emitting element layer 130 may be formed on the backplane layer 120. For example, the first electrode ET1 of the light emitting element ED, the pixel defining layer 131, the light emitting layer EML of the light emitting element ED, and the second electrode ET2 of the light emitting element ED may be sequentially formed on the sixth insulating layer 128. Accordingly, the light emitting element ED may be formed in each light emission area EA.

The first electrode ET1 of the light emitting element ED may fill the via hole VH for exposing the fifth connection electrode CNE5 of each subpixel SPX. Accordingly, the first electrode ET1 of the light emitting element ED may be electrically connected to the fifth connection electrode CNE5, and may be electrically connected to at least one circuit element (e.g., the first switching transistor ST1 of FIG. 24) included in each subpixel SPX through the fifth connection electrode CNE5 and the second connection electrode CNE2.

Through the above-described process, the backplane layer 120 and the light emitting element layer 130 of the display panel 100 according to one or more embodiments may be formed. As shown in FIG. 9, when the display panel 100 includes the encapsulation layer 140, the encapsulation layer 140 may be formed on the light emitting element layer 130. For example, the first encapsulation layer (e.g., first inorganic encapsulation layer) 141, the second organic encapsulation layer 143, and the third encapsulation layer (e.g., second inorganic encapsulation layer) 145 may be sequentially formed on the second electrode ET2 (or the inorganic capping layer covering the light emitting element ED) of the light emitting element ED. In one or more embodiments, when the display panel 100 further includes additional elements (e.g., a light conversion layer, a color filter layer, a touch sensing layer 150 of FIG. 4 and/or an additional optical layer 160 of FIG. 4) in addition to the elements shown in FIG. 9, the manufacturing process of the display panel 100 may further include a step of forming or arranging the additional elements.

Through the above-described process, the display panel 100 including the driving transistor DT according to one or more embodiments and the display device 1 including the display panel 100 may be manufactured.

The display device 1 (or the display module 11) according to at least one of the above-described embodiments may be applied to various electronic devices. The electronic device according to one or more embodiments includes the above-described display device 1 or the display module 11, and may further include a module or device having other additional functions in addition to the display device 1 or the display module 11.

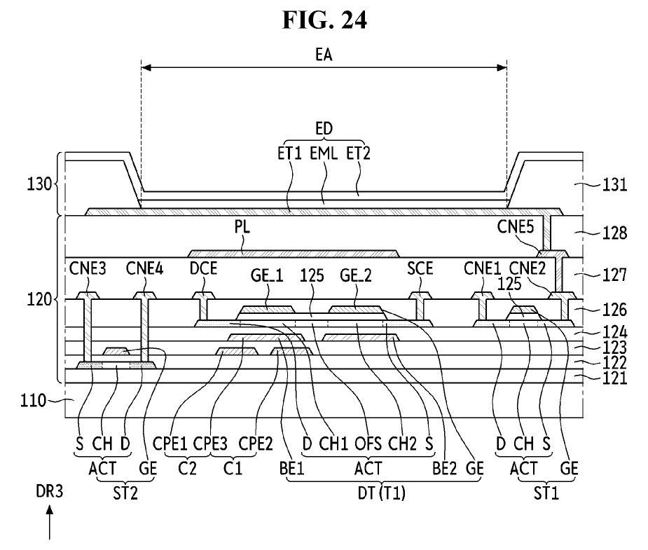

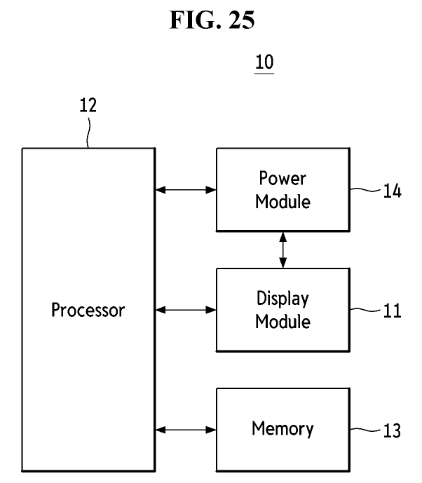

FIG. 25 is a block diagram illustrating an electronic device according to one embodiment.

Referring to FIG. 25, an electronic device 10 according to one or more embodiments may include a display module 11, a processor 12, a memory 13, and a power module 14.

The electronic device 10 may output various kinds of information in the form of an image through the display module 11. For example, when the processor 12 executes an application stored in the memory 13, image information provided by the application may be provided to a user through the display module 11. The display module 11 according to one or more embodiments may include the display panel 100 according to the above-described embodiments.

The processor 12 may include at least one of a central processing unit (CPU), an application processor (AP), a graphic processing unit (GPU), a communication processor (CP), an image signal processor (ISP), or a controller.

Data information required for an operation of the processor 12 or the display module 11 may be stored in the memory 13. For example, the memory 13 may store an image data signal and/or an input control signal.

The processor 12 may control the display module 11 by using the information stored in the memory 13. The processor 12 may transmit the image data signal and/or the input control signal, which are/is stored in the memory 13, to the display module 11. For example, when the processor 12 executes the application stored in the memory 13, the image data signal and/or the input control signal is transmitted to the display module 11, and the display module 11 may process the received signal and output image information through a display screen.

The power module 14 may include a power supply module such as a power adapter or a battery device, and a power conversion module converting a power source supplied by the power supply module to generate a power source required for the operation of the electronic device 10.

At least one of the respective components of the above-described electronic device 10 may be included in the display device 1 according to the above-described embodiments. Also, some of the individual modules functionally included in one module may be included in the display device 1, and others thereof may be provided separately from the display device 1. For example, the display device 1 includes a display module 11, and the processor 12, the memory 13, and the power module 14 may be provided as other devices in the electronic device 10 not the display device 1.

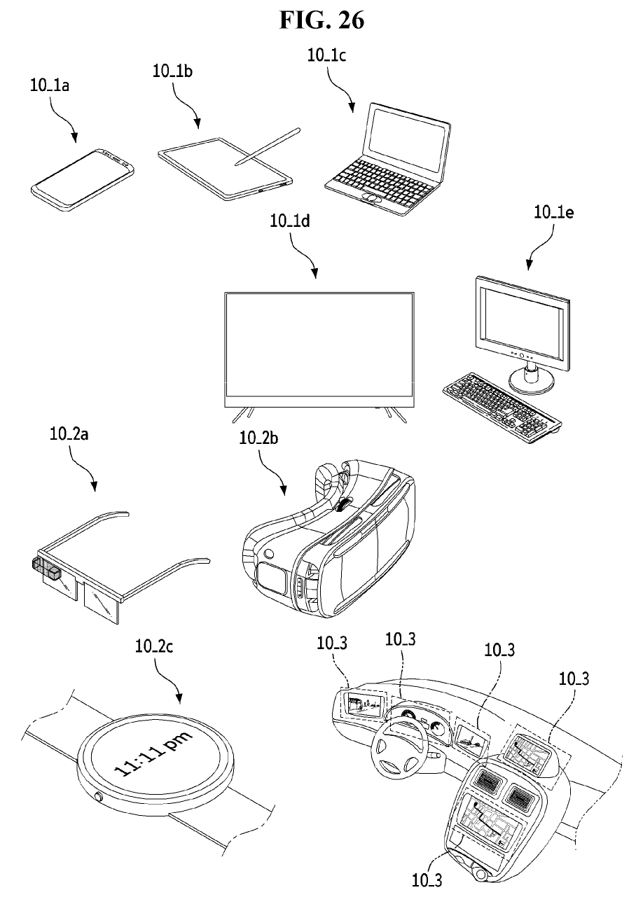

FIG. 26 illustrates schematic diagrams of electronic devices according to various embodiments.

Referring to FIG. 26, various electronic devices to which the display devices 1 according to one or more embodiments are applied may include not only electronic devices for image display, such as a smart phone 10_1a, a tablet PC 10_1b, a laptop 10_1c, a TV 10_1d, and a desk monitor 10_1e, but also wearable electronic devices including display modules such as smart glasses 10_2a, a head mounted display 10_2b, and a smart watch 10_2c, and a vehicle electronic device 10_3 including display modules such as a vehicle dashboard, a center fascia, a center information display (CID) arranged on the dashboard, and/or a room mirror display.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
a driving transistor comprising a first bottom electrode and a second bottom electrode on the substrate, an active layer comprising a first channel region and a second channel region on the first and second bottom electrodes, and a gate electrode on the first and second channel regions;
an insulating layer covering the driving transistor; and
a light emitting element on the insulating layer,
wherein the active layer further comprises an offset region located between the first channel region and the second channel region.

2. The display device of claim 1, wherein the active layer further comprises a drain region on one side of the first channel region and a source region on one side of the second channel region,
wherein the first bottom electrode is electrically connected to the source region, and
wherein the second bottom electrode is electrically connected to the gate electrode.

3. The display device of claim 2, further comprising:
a source connection electrode electrically connected to the first bottom electrode and the source region; and
a drain connection electrode electrically connected to the drain region.

4. The display device of claim 1, wherein the gate electrode comprises a first portion on the first channel region and a second portion on the second channel region, and
wherein the first portion and the second portion of the gate electrode are spaced from each other at a portion where the active layer and the gate electrode overlap each other.

5. The display device of claim 1, wherein the first bottom electrode and the second bottom electrode are spaced from each other on a same layer.

6. The display device of claim 1, wherein the first bottom electrode and the second bottom electrode are patterns of different conductive layers arranged on the substrate.

7. The display device of claim 6, wherein a distance between the first bottom electrode and the first channel region is less than a distance between the second bottom electrode and the second channel region.

8. The display device of claim 6, wherein the first bottom electrode and the second bottom electrode do not overlap each other in a thickness direction of the substrate.

9. The display device of claim 6, wherein the first bottom electrode and the second bottom electrode overlap each other below the offset region.

10. The display device of claim 1, further comprising a gate insulating layer between the active layer and the gate electrode,
wherein the gate insulating layer covers a portion of the active layer comprising the first channel region, the second channel region, and the offset region, the gate insulating layer being etched to expose another portion of the active layer.

11. The display device of claim 1, wherein the active layer comprises an oxide semiconductor.

12. An electronic device comprising:
a display module comprising a display panel; and
a processor configured to transmit an image data signal to the display module,
wherein the display panel comprises:
a substrate;
a driving transistor comprising a first bottom electrode and a second bottom electrode on the substrate, an active layer comprising a first channel region and a second channel region on the first and second bottom electrodes, and a gate electrode on the first and second channel regions;
an insulating layer covering the driving transistor; and
a light emitting element on the insulating layer,
wherein the active layer further comprises an offset region located between the first channel region and the second channel region.

13. The electronic device of claim 12, wherein the active layer further comprises a drain region on one side of the first channel region and a source region on one side of the second channel region,
wherein the first bottom electrode is electrically connected to the source region, and
wherein the second bottom electrode is electrically connected to the gate electrode.

14. The electronic device of claim 12, wherein the gate electrode comprises a first portion on the first channel region and a second portion on the second channel region, and
wherein the first portion and the second portion of the gate electrode are spaced from each other at a portion where the active layer and the gate electrode overlap each other.

15. A method for manufacturing a display device, the method comprising:
forming a first bottom electrode and a second bottom electrode, and an insulating layer covering the first bottom electrode and the second bottom electrode, on a substrate;
sequentially forming an active layer, a gate insulating layer, and a conductive film, on the insulating layer;
forming a mask pattern on the conductive film, the mask pattern overlapping a portion including a central portion of the active layer, having a first thickness at a first portion, and having a second thickness greater than the first thickness at a second portion on respective sides of the first portion;
forming a gate electrode below the mask pattern by etching the conductive film using the mask pattern;
exposing a portion of the gate electrode by removing the first portion of the mask pattern;
etching the portion of the gate electrode; and
removing the mask pattern.

16. The method of claim 15, wherein the forming the mask pattern comprises:
forming a photosensitive film on the conductive film;
arranging a halftone mask on the photosensitive film and then exposing the photosensitive film using the halftone mask; and
forming the mask pattern by developing the photosensitive film.

17. The method of claim 16, wherein the exposing the photosensitive film using the halftone mask comprises:
arranging a half-tone portion of the halftone mask on a portion of the photosensitive film, which corresponds to a portion where the first portion of the mask pattern is to be formed; and
arranging a non-tone portion of the halftone mask on another portion of the photosensitive film, which corresponds to a portion where the second portion of the mask pattern is to be formed.

18. The method of claim 15, further comprising etching the gate insulating layer in a form corresponding to the gate electrode before removing the first portion of the mask pattern.

19. The method of claim 15, further comprising forming another portion of the active layer, which is not covered by the gate electrode and the mask pattern, as a source region and a drain region before removing the first portion of the mask pattern.

20. The method of claim 15, further comprising:
forming an interlayer insulating layer covering the active layer, the gate insulating layer, and the gate electrode; and
forming a connection electrode electrically connected to the active layer, on the interlayer insulating layer.
